(19) United States
(12) Patent Application Publication
(10) Pub. No.: US 2025/0329378 A1
(43) Pub. Date: Oct. 23, 2025

(54) SEMICONDUCTOR MEMORY DEVICES

(71) Applicant: Samsung Electronics Co., Ltd., Suwon-si (KR)

(72) Inventors: Yoojong Lee, Suwon-si (KR); Suyeon Doo, Suwon-si (KR); Hyungjoon Chi, Suwon-si (KR)

(21) Appl. No.: 19/077,197

(22) Filed: Mar. 12, 2025

(30) Foreign Application Priority Data
Apr. 17, 2024 (KR) 10-2024-0051519
Jun. 7, 2024 (KR) 10-2024-0074404

(51) Int. Cl. G11C 11/4096; G11C 11/408; G11C 11/4093

(52) U.S. Cl. CPC G11C 11/4096; G11C 11/408; G11C 11/4093

(57) ABSTRACT

A semiconductor memory device comprising: a memory cell array including first and second storage regions; first data pins receive write data in a byte mode; second data pins unused in the byte mode; a first global write circuit connected to the first data pins; a center-bus circuit connected to the first global write circuit to provide the write data to a first connection terminal in a first write mode in the first storage region and to provide the write data to a second connection terminal in a second write mode in the second storage region, wherein the first global write circuit provides the write data to the center-bus circuit; a first local write circuit writes the write data from the first connection terminal to the first storage region; and a second local write circuit writes the write data from the second connection terminal to the second storage region.

### CROSS-REFERENCE TO RELATED APPLICATIONS

This application claims priority under 35 U.S.C. § 119 to Korean Patent Application Nos. 10-2024-0051519 filed on Apr. 17, 2024, and 10-2024-0074404 filed on Jun. 7, 2024, in the Korean Intellectual Property Office, the disclosures of which are incorporated by reference herein in their entireties.

### BACKGROUND OF THE INVENTION

Embodiments of the present disclosure described herein relate to electronic devices, and more particularly, relate to semiconductor memory devices.

A semiconductor memory device may be classified as a volatile memory device or a nonvolatile memory device. The volatile memory device may retain data stored therein while a power is supplied, and the nonvolatile memory device may retain data stored therein even though a power is turned off. The volatile memory device may provide a fast speed (a faster speed than the nonvolatile memory device), and the nonvolatile memory device may provide excellent safety and endurance (better safety and endurance than the volatile memory device).

To increase the storage capacity of the semiconductor memory device and to make the degree of integration of the semiconductor memory device higher, nowadays, there are being developed a cell over periphery (COP) structure and a periphery over cell (POC) structure in which memory cells are arranged three-dimensionally instead of two-dimensionally. In the COP structure, peripheral circuits are disposed under (below) memory cells, and in the POC structure, most of peripheral circuits are disposed over (above) memory cells. There is a need for a method for decreasing the complexity or area of peripheral circuits, in particular, a data input/output circuit in the semiconductor memory device.

### SUMMARY OF THE INVENTION

Embodiments of the present disclosure may provide a semiconductor memory device capable of decreasing the complexity or area of a data input/output circuit.

According to an embodiment, a semiconductor memory device comprising: a memory cell array including a first storage region and a second storage region; a plurality of first data pins configured to receive write data in a byte mode of the semiconductor memory device; a plurality of second data pins configured to be unused in the byte mode and configured to receive the write data in a standard mode of the semiconductor memory device; a first global write circuit electrically connected to the plurality of first data pins; a center-bus circuit electrically connected to the first global write circuit and configured to provide the write data to a first connection terminal in a first write mode of writing the write data in the first storage region and to provide the write data to a second connection terminal in a second write mode of writing the write data in the second storage region, wherein the first global write circuit is configured to provide the write data to the center-bus circuit; a first local write circuit configured to write the write data from the first connection terminal to the first storage region; and a second local write circuit configured to write the write data from the second connection terminal to the second storage region.

According to an embodiment, a semiconductor memory device comprising: a memory cell array including a first storage region and a second storage region, wherein the first storage region has first data, and the second storage region has second data; a plurality of first data pins configured to output the first data and/or the second data in a byte mode of the semiconductor memory device; a plurality of second data pins configured to be unused in the byte mode and configured to output the second data in a standard mode of the semiconductor memory device; a first local read circuit electrically connected to the first storage region and configured to output the first data; a second local read circuit electrically connected to the second storage region and configured to output the second data; a center-bus circuit configured to output the first data to a first connection terminal in a first read mode of outputting the first data to the plurality of first data pins and to output the second data to a second connection terminal in a second read mode of outputting the second data to the plurality of first data pins; and a first global read circuit electrically connected to the plurality of first data pins and configured to output the first data from the first connection terminal to the plurality of first data pins and to output the second data from the second connection terminal to the plurality of first data pins.

According to an embodiment, a semiconductor memory device comprising: a memory cell array including a first storage region and a second storage region; a plurality of first data pins configured to be used in a byte mode of the semiconductor memory device; and a center-bus circuit configured to provide a path for data transmission between the plurality of first data pins and the first storage region in a first write/read mode of performing a first write operation or a first read operation on the first storage region and to provide a path for data transmission between the plurality of first data pins and the second storage region in a second write/read mode of performing a second write operation or a second read operation on the second storage region, wherein the center-bus circuit comprises: a first multiplexer and a first center write buffer for the first write operation on the first storage region in the first write/read mode; and a second multiplexer and a second center write buffer for the second write operation on the second storage region in the second write/read mode.

### BRIEF DESCRIPTION OF THE FIGURES

The above and other objects and features of the present disclosure will become more apparent by describing in detail embodiments thereof with reference to the accompanying drawings.

FIG. 1 is a block diagram illustrating a semiconductor memory device according to some embodiments of the present disclosure.

FIG. 2 is a diagram for describing semiconductor memory devices implemented to operate in a byte mode.

FIG. 3 is a block diagram illustrating a semiconductor memory device according to some embodiments of the present disclosure.

FIG. 4 is a block diagram for describing an example embodiment of components of a semiconductor memory device including a center-bus circuit of FIG. 3.

FIG. 5 is a diagram for describing a byte mode setting signal of FIG. 3.

FIGS. 6A and 6B are diagrams for describing an expanded address value of FIG. 3.

FIG. 7 is a diagram illustrating an example embodiment of a center-bus control circuit of FIG. 3.

FIGS. 8A, 8B, and 8C are timing diagrams for describing an operation of a semiconductor memory device of FIG. 3.

FIG. 9 is a block diagram illustrating a semiconductor memory device according to some embodiments of the present disclosure.

FIG. 10 is a block diagram for describing an example embodiment of components of a semiconductor memory device including a center-bus circuit of FIG. 9.

FIG. 11 is a diagram illustrating an example embodiment of a center-bus control circuit of FIG. 9.

FIGS. 12A, 12B, and 12C are timing diagrams for describing an operation of a semiconductor memory device of FIG. 9.

FIG. 13 is a block diagram illustrating a semiconductor memory device according to some embodiments of the present disclosure.

FIG. 14 is a block diagram for describing an example embodiment of components of a semiconductor memory device including a center-bus circuit of FIG. 13.

FIGS. 15A and 15B are diagrams for describing locations where center-bus circuits of FIGS. 3, 8, and 13 are disposed.

FIG. 16 is a block diagram illustrating a volatile memory device according to some embodiments of the present disclosure.

FIG. 17 is a block diagram illustrating a data center including a semiconductor memory device according to some embodiments of the present disclosure.

### DETAILED DESCRIPTION

Below, embodiments of the present disclosure will be described in detail and clearly to such an extent that one skilled in the art easily carries out the present disclosure.

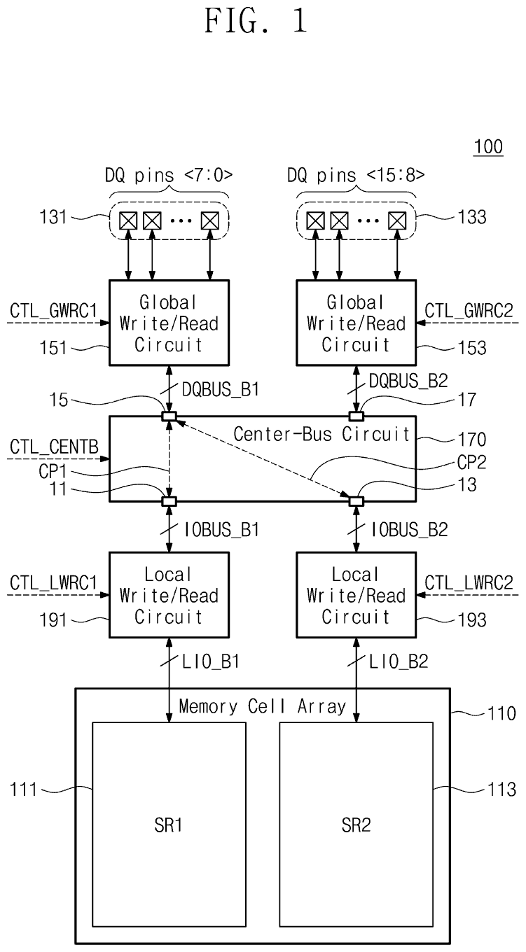

FIG. 1 is a block diagram illustrating a semiconductor memory device according to some embodiments of the present disclosure.

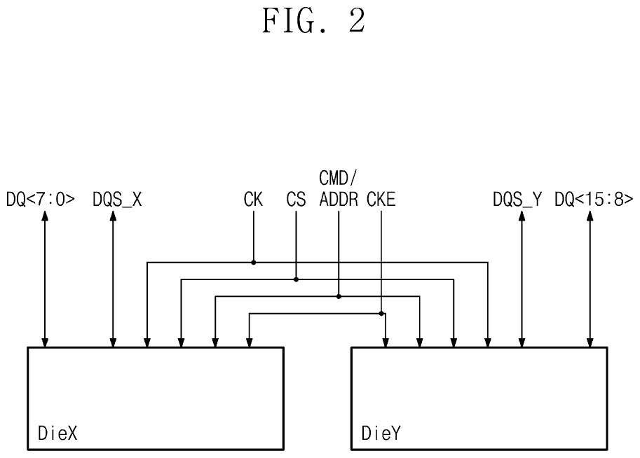

Referring to FIG. 1, a semiconductor memory device 100 may include a memory cell array 110, a plurality of first data pins 131 (marked by DQ pins<7:0> in FIG. 1), a plurality of second data pins 133 (marked by DQ pins<15:8> in FIG. 1), a first global write/read circuit 151, a second global write/read circuit 153, a center-bus circuit 170, a first local write/read circuit 191, and a second local write/read circuit 193. In an example embodiment, the semiconductor memory device 100 may include a dynamic random access memory (DRAM), a double data rate 4 (DDR4) synchronous DRAM (SDRAM), a low power DDR4 (LPDDR4) SDRAM, an LPDDR5 SDRAM, a graphics double data rate5 (GDDR5) SDRAM, a GDDR6 SDRAM, a high bandwidth memory 2 (HBM2), an HBM2E, and/or an HBM3, which are capable of operating in a standard mode and/or a byte mode (or in which the standard mode and/or the byte mode are implemented or which are capable of supporting the standard mode and/or the byte mode), but the present disclosure is not limited thereto. For example, the standard mode may refer to an operation mode in which data is written to or read from using both the plurality of first data pins 131 and the plurality of second data pins 133, or an operation mode in which data is input or output through both the plurality of first data pins 131 and the plurality of second data pins 133. For example, the byte mode may refer to an operation mode in which data is written to or read from using only one of the plurality of first data pins 131 and the plurality of second data pins 133, or an operation mode in which data is input or output through only one of the plurality of first data pins 131 and the plurality of second data pins 133. For example, an external host may configure one channel with a semiconductor memory device operating in the standard mode or one channel with two semiconductor memory devices operating in the byte mode to perform operations to input or output data. The byte mode will be described with reference to FIG. 2.

The memory cell array 110 may include a first storage region (SR1) 111 and a second storage region (SR2) 113. For example, when the semiconductor memory device 100 operates in the standard mode, the first storage region 111 may refer to a region where pieces of data input/output through the plurality of first data pins 131 are written or read. When the semiconductor memory device 100 operates in the byte mode, the first storage region 111 may be a region where the semiconductor memory device 100 configured to operate in the byte mode using the plurality of first data pins 131 stores data input through the plurality of first data pins 131 before the second storage region 133. For example, when the semiconductor memory device 100 operates in the standard mode, the second storage region 113 may refer to a region where pieces of data input/output through the plurality of second data pins 133 are written or read. When the semiconductor memory device 100 operates in the byte mode, the second storage region 113 may be a region where the semiconductor memory device 100 configured to operate in the byte mode using the plurality of second data pins 133 stores data input through the plurality of second data pins 133 before the first storage region 111.

The data may be written or read in or from the memory cell array 110 through the plurality of first data pins 131 and the plurality of second data pins 133. However, in the byte mode of the semiconductor memory device 100, when one group of data pins (e.g., the first data pins 131 or the second data pins 133) participates in the input/output of data, the other group of data pins (e.g., the second data pins 133 or the first data pins 131) may not participate in the input/output of data. For example, in the byte mode, when the data is input/output through the plurality of first data pins 131, the plurality of second data pins 133 may be unused. For example, in the byte mode, when the data is input/output through the plurality of second data pins 133, the plurality of first data pins 131 may be unused. Herein, “unused” element A may refer to deactivation or inactivation of element A through a hardware manner, such as floating, grounding, applying high impedance, etc., or a software manner, such as programming.

In the byte mode, for example, when the data is input/output through the plurality of first data pins 131, the first global write/read circuit 151 may provide the data transferred from the plurality of first data pins 131 to the center-bus circuit 170 or may provide the data transferred from the center-bus circuit 170 to the plurality of first data pins 131.

In the byte mode, for example, when the data is input/output through the plurality of first data pins 131, the center-bus circuit 170 may provide the data transferred from the first global write/read circuit 151 to (at least) one of the first local write/read circuit 191 and the second local write/read circuit 193 and may provide the data transferred from (at least) one of the first local write/read circuit 191 and the second local write/read circuit 193 to the first global write/read circuit 151.

The first local write/read circuit 191 may write the data transferred from the center-bus circuit 170 in the first storage region 111 and may read the data from the first storage region 111 so as to be provided to the center-bus circuit 170.

The second local write/read circuit 193 may write the data transferred from the center-bus circuit 170 in the second storage region 113 and may read the data from the second storage region 113 so as to be provided to the center-bus circuit 170.

In an example embodiment, in the standard mode, the second global write/read circuit 153 may participate in writing and/or reading data through the plurality of second data pins 133 in a manner the same as or similar to that of the first global write/read circuit 151. However, when the plurality of second data pins 133 are unused in the byte mode, the second global write/read circuit 153 may also be unused.

In an example embodiment, the first global write/read circuit 151, the second global write/read circuit 153, the center-bus circuit 170, the first local write/read circuit 191, and the second local write/read circuit 193 may be configured to perform bidirectional communication. For example, data DQBUS_B1 may be exchanged between the first global write/read circuit 151 and the center-bus circuit 170, and data DQBUS_B2 may be exchanged between the second global write/read circuit 153 and the center-bus circuit 170. For example, data IOBUS_B1 may be exchanged between the center-bus circuit 170 and the first local write/read circuit 191, and data IOBUS_B2 may be exchanged between the center-bus circuit 170 and the second local write/read circuit 193. Data LIO_B1 may be exchanged between the first local write/read circuit 191 and the first storage region 111, and data LIO_B2 may be exchanged between the second local write/read circuit 193 and the second storage region 113.

In the byte mode, the semiconductor memory device 100 may operate in a first write/read mode and a second write/read mode.

In an example embodiment, in the byte mode, for example, when the data is input/output through the plurality of first data pins 131, the first write/read mode may refer to an operation mode in which a write or read operation is performed for the first storage region 111, and the second write/read mode may refer to an operation mode in which a write or read operation is performed for the second storage region 113. In the byte mode, for example, when the data is input/output through the plurality of second data pins 133, the first write/read mode may refer to an operation mode in which a write or read operation is performed for the second storage region 113, and the second write/read mode may refer to an operation mode in which a write or read operation is performed for the first storage region 111.

In an example embodiment, in the byte mode, for example, when the data is input/output through the plurality of first data pins 131, in the first write/read mode, the center-bus circuit 170 may provide a path for data transmission (e.g., CP1) between the plurality of first data pins 131 and the first storage region 111; in the second write/read mode, the center-bus circuit 170 may provide a path for data transmission (e.g., CP2) between the plurality of first data pins 131 and the second storage region 113. The center-bus circuit 170 may include connection terminals 11, 13, 15, and 17 (e.g., a first connection terminal 11, a second connection terminal 13, a third connection terminal 15, and a fourth connection terminal 17) for communicating with peripheral write/read circuits (the first global write/read circuit 151, the second global write/read circuit 153, the first local write/read circuit 191, and the second local write/read circuit 193). The connection terminal 17 may not be used in the byte mode (e.g., in the first write/read mode and the second write/read mode), and each of the connection terminals 11, 13, 15, and 17 may be used as an input terminal and/or an output terminal depending on an operation mode.

Control signals CTL_GWRC1, CTL_GWRC2, CTL_CENTB, CTL_LWRC1, and CTL_LWRC2 for the operations of the first global write/read circuit 151, the second global write/read circuit 153, the center-bus circuit 170, the first local write/read circuit 191, and the second local write/read circuit 193 may be provided from the outside or inside of the semiconductor memory device 100. In particular, the control signal CTL_CENTB provided to the center-bus circuit 170 may be referred to as a “center-bus control signal”.

The first data pins 131, the second data pins 133, the first global write/read circuit 151, the second global write/read circuit 153, the center-bus circuit 170, the first local write/read circuit 191, and the second local write/read circuit 193 of the semiconductor memory device 100 may be collectively referred to as a “data input/output circuit”.

According to the above configuration, a semiconductor memory device according to embodiments of the present disclosure may include a center-bus circuit which provides paths for data transmission between global write/read circuits and local write/read circuits. The semiconductor memory device may not include additional circuits between the global write/read circuits and the local write/read circuits except for the center-bus circuit and may not include any other additional global or local lines, and the center-bus circuit may not be implemented on (or adjacent) the global write/read circuit side but may be implemented on (or adjacent) the local write/read circuit side. Accordingly, a semiconductor memory device may implement a byte mode of the semiconductor memory device by using the center-bus circuit and may decrease the complexity or area of the entire data input/output circuit by decreasing the complexity or area of the global write/read circuits.

FIG. 2 is a diagram for describing semiconductor memory devices implemented to operate in a byte mode.

Referring to FIG. 2, a first semiconductor memory device DieX and a second semiconductor memory device DieY may be configured to operate in the byte mode. For example, the first semiconductor memory device DieX may be configured to input or output data signals DQ<7:0> using only a plurality of first data pins (for example, 133 of FIG. 1), and the second semiconductor memory device DieY may be configured to input or output data signal DQ<15:8> using only a plurality of second data pins (for example, 133 in FIG. 1). Each of the first semiconductor memory device DieX and the second semiconductor memory device Die Y may be referred to as a “die” or “chip”.

As illustrated in FIG. 2, in the byte mode, the first semiconductor memory device DieX and the second semiconductor memory device DieY may receive a clock signal CK, a chip select signal CS, a command/address signal CMD/ADDR, a clock enable signal CKE, etc. in command.

In the byte mode, the first semiconductor memory device DieX may independently transmit/receive data signals DQ<7:0> and a data strobe signal DQS_X, for example, using the plurality of first data pins, and the second semiconductor memory device DieY may independently transmit/receive data signals DQ<15:8> and a data strobe signal DQS_Y, for example, using the plurality of second data pins.

In an example embodiment, the data signals DQ<7:0> and the data signals DQ<15:8> may form one channel, and each of the first semiconductor memory device DieX and the second semiconductor memory device DieY may perform an input/output for half the data signals associated with one channel. In the standard mode of the semiconductor memory device distinguished from the byte mode, unlike as illustrated in FIG. 2, one semiconductor memory device may perform an input/output for all the data signals associated with one channel using all of the plurality of first data pins and the plurality of second data pins.

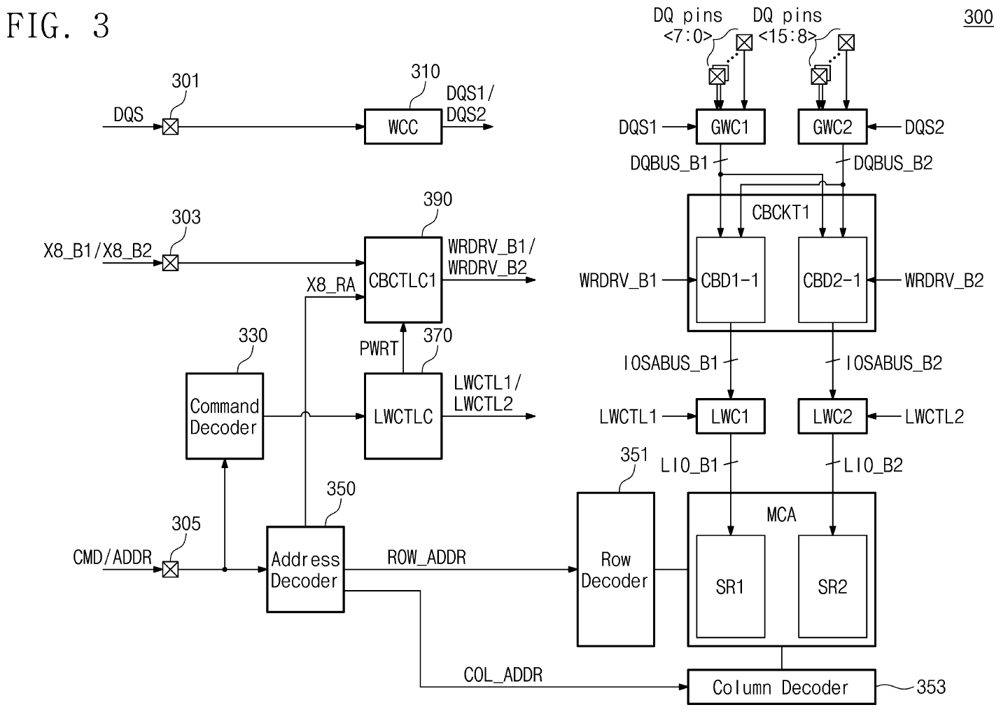

FIG. 3 is a block diagram illustrating a semiconductor memory device according to some embodiments of the present disclosure.

Referring to FIG. 3, a semiconductor memory device 300 may correspond to the semiconductor memory device 100 of FIG. 1. The semiconductor memory device 300 may include a memory cell array MCA including the first storage region SR1 and the second storage region SR2, the plurality of first data pins DQ pins<7:0>, the plurality of second data pins DQ pins<15:8>, a first global write circuit GWC1, a second global write circuit GWC2, a center-bus circuit CBCKT1, a first local write circuit LWC1, and a second local write circuit LWC2, and components which are marked by reference numerals/signs the same as or similar to those of the components included in the semiconductor memory device 100 may perform the same or similar functions. Referring to FIG. 3, the semiconductor memory device 300 may correspond to the semiconductor memory device 100 which performs the “write operation”.

The semiconductor memory device 300 may further include a data strobe pin 301 receiving the data strobe signal DQS, a byte mode setting pin 303 receiving a byte mode setting signal including setting signals X8_B1 and X8_B2, a command/address pin 305 receiving a command signal CMD and an address signal ADDR (the command/address signal CMD/ADDR), a write clock circuit (WCC) 310, a command decoder 330, an address decoder 350, a row decoder 351, a column decoder 353, a center-bus control circuit (CBCTLC1) 390, and a local write control circuit (LWCTLC) 370.

The write clock circuit 310 may provide signals DQS1 and DQS2 to the first global write circuit GWC1 and the second global write circuit GWC2 based on the data strobe signal DQS.

The command decoder 330, the address decoder 350, the row decoder 351, and the column decoder 353 may correspond to components of a conventional semiconductor memory device, and the local write control circuit 370 may provide control signals LWCTL1 and LWCTL2 to the first local write circuit LWC1 and the second local write circuit LWC2 under control of the command decoder 330.

The center-bus control circuit 390 may receive the byte mode setting signal from the byte mode setting pin 303, may receive an expanded address value X8_RA from the address decoder 350, and may receive a write strobe signal PWRT from the local write control circuit 370. For example, the byte mode setting signal may indicate whether the semiconductor memory device 300 is implemented to operate in the byte mode and may include the first setting signal X8_B1 and the second setting signal X8_B2. The first setting signal X8_B1 may be associated with a plurality of first data pins DQ pins<7:0>, and the second setting signal X8_B2 may be associated with a plurality of second data pins DQ pins<15:8>. For example, the address signal ADDR may include the expanded address value X8_RA in the byte mode, and the expanded address value X8_RA may indicate that the semiconductor memory device 300 operates in a first write mode and a second write mode. When the semiconductor memory device 300 is configured to input or output data using the plurality of first data pins DQ pins<7:0>, the first write mode may refer to an operation mode in which write data received through the plurality of first data pins DQ pins<7:0> are written in the first storage region SR1, and the second write mode may refer to an operation mode in which the write data are written in the second storage region SR2. The first storage region SR1 and the second storage region SR2 are the same as those described with reference to FIG. 1 in association with the standard mode and the byte mode.

The center-bus control circuit 390 may generate a center-bus control signal based on the byte mode setting signal and the address signal ADDR and may control the center-bus circuit CBCKT1 based on the center-bus control signal. For example, the center-bus control circuit 390 may provide control signals WRDRV_B1 and WRDRV_B2 to the center-bus circuit CBCKT1, based on the first setting signal X8_B1, the second setting signal X8_B2, the expanded address value X8_RA, and the write strobe signal PWRT. The center-bus circuit CBCKT1 may include a first center-bus driver CBD1-1 and a second center-bus driver CBD2-1, the control signal WRDRV_B1 may be provided to the first center-bus driver CBD1-1, and the control signal WRDRV_B2 may be provided to the second center-bus driver CBD2-1.

In an example embodiment, in the byte mode of the semiconductor memory device 300, when the semiconductor memory device 300 is configured to use the plurality of first data pins DQ pins<7:0>, the plurality of first data pins DQ pins<7:0> may receive write data. In this case, the plurality of second data pins DQ pins<15:8> may be unused in the byte mode.

In an example embodiment, the first global write circuit GWC1 may be (electrically) connected to the plurality of first data pins DQ pins<7:0> and may provide the write data. The center-bus circuit CBCKT1 may be (electrically) connected to the first global write circuit GWC1. In the first write mode of storing the write data in the first storage region SR1, the center-bus circuit CBCKT1 may provide the write data to the first connection terminal; in the second write mode of storing the write data in the second storage region SR2, the center-bus circuit CBCKT1 may provide the write data to the second connection terminal.

In an example embodiment, the first local write circuit LWC1 may write the write data provided through the first connection terminal in the first storage region SR1, and the second local write circuit LWC2 may write the write data provided through the second connection terminal in the second storage region SR2.

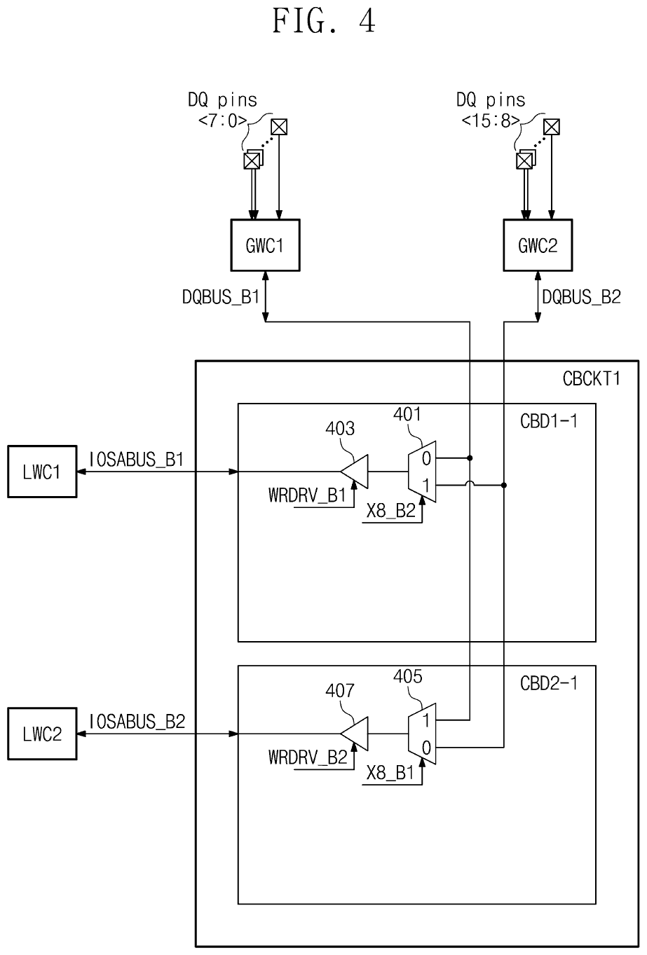

FIG. 4 is a block diagram for describing an example embodiment of components of a semiconductor memory device including a center-bus circuit of FIG. 3.

For convenience of description, only some of the components of the semiconductor memory device 300 of FIG. 3 are illustrated in FIG. 4. In FIGS. 3 and 4, components which are marked by the same reference numerals/signs may perform the same or similar functions.

Referring to FIGS. 3 and 4, the center-bus circuit CBCKT1 may include the first center-bus driver CBD1-1 and the second center-bus driver CBD2-1.

In an example embodiment, in the byte mode, when the semiconductor device 300 is configured to use the plurality of first data pins DQ pins<7:0>, in the first write mode, the first center-bus driver CBD1-1 may receive the write data from the first global write circuit GWC1 and may output the write data to the first local write circuit LWC1. In the second write mode, the second center-bus driver CBD2-1 may receive the write data from the first global write circuit GWC1 and may output the write data to the second local write circuit LWC2. In the byte mode, when the semiconductor device 300 is configured to use the plurality of second data pins DQ pins<15:8>, in the first write mode, the second center-bus driver CBD2-1 may receive the write data from the first global write circuit GWC1 and may output the write data to the second local write circuit LWC2. In the second write mode, the first center-bus driver CBD1-1 may receive the write data from the second global write circuit GWC2 and may output the write data to the first local write circuit LWC1.

In an example embodiment, the first center-bus driver CBD1-1 may include a first multiplexer 401 and a first center write driver 403. For example, in the byte mode, the semiconductor memory device 300 is configured to use the plurality of first data pins DQ pins<7:0>, in the first write mode, the first multiplexer 401 may select and output the write data output from the first global write circuit GWC1. The first center write driver 403 may output the write data output from the first multiplexer 401 to the first local write circuit LWC1. The first multiplexer 401 may select the write data in the first write mode based on the second setting signal X8_B2, and the first center write driver 403 may output the write data based on the control signal WRDRV_B1.

In an example embodiment, the second center-bus driver CBD2-1 may include a second multiplexer 405 and a second center write driver 407. For example, in the byte mode, the semiconductor memory device 300 is configured to use the plurality of first data pins DQ pins<7:0>, in the second write mode, the second multiplexer 405 may select and output the write data output from the first global write circuit GWC1. The second center write driver 407 may output the write data output from the second multiplexer 405 to the second local write circuit LWC2. The second multiplexer 405 may select the write data in the second write mode based on the first setting signal X8_B1, and the second center write driver 407 may output the write data based on the control signal WRDRV_B2.

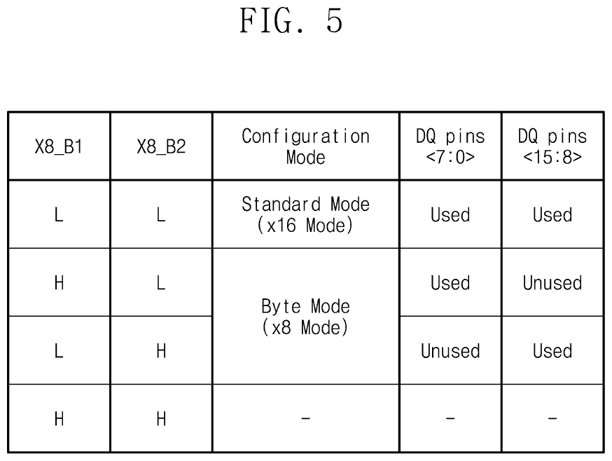

FIG. 5 is a diagram for describing a byte mode setting signal of FIG. 3.

As described with reference to FIG. 3, the byte mode setting signal may indicate whether a semiconductor memory device (e.g., 300 of FIG. 3) is implemented to operate in the byte mode and may include the first setting signal X8_B1 and the second setting signal X8_B2.

Referring to FIG. 5, each of the first setting signal X8_B1 and the second setting signal X8_B2 may have one of a first logic level (e.g., logic high “H”) and a second logic level (e.g., logic low “L”).

In an example embodiment, the case where both the first setting signal X8_B1 and the second setting signal X8_B2 have the second logic level may indicate that the semiconductor memory device operates in the standard mode. The standard mode may be referred to as a “×16 mode”. In this case, both the first data pins DQ pins<7:0> and the second data pins DQ pins<15:8> may be used for a data input/output.

In an example embodiment, the case where one of the first setting signal X8_B1 and the second setting signal X8_B2 has the first logic level and the other thereof has the second logic level may indicate that the semiconductor memory device operates in the byte mode. The byte mode may be referred to as a “×8 mode”. In this case, in one semiconductor memory device, either the first data pins DQ pins<7:0> or the second data pins DQ pins<15:8> may be used for a data input/output. For example, in the byte mode, when a semiconductor memory device is configured to input or output using the plurality of data pins DQ pins<7:0>, then for the semiconductor memory device, the first setting signal X8_B1 may have the first logic level, and the second setting signal X8_B2 may have the second logic level. For example, in the byte mode, when a semiconductor memory device is configured to input or output using the plurality of data pins DQ pins<15:8>, then for the semiconductor memory device, the first setting signal X8_B1 may have the second logic level, and the first setting signal X8_B2 may have the first logic level.

In an embodiment, the case where both the first setting signal X8_B1 and the second setting signal X8_B2 have the first logic level may not be defined.

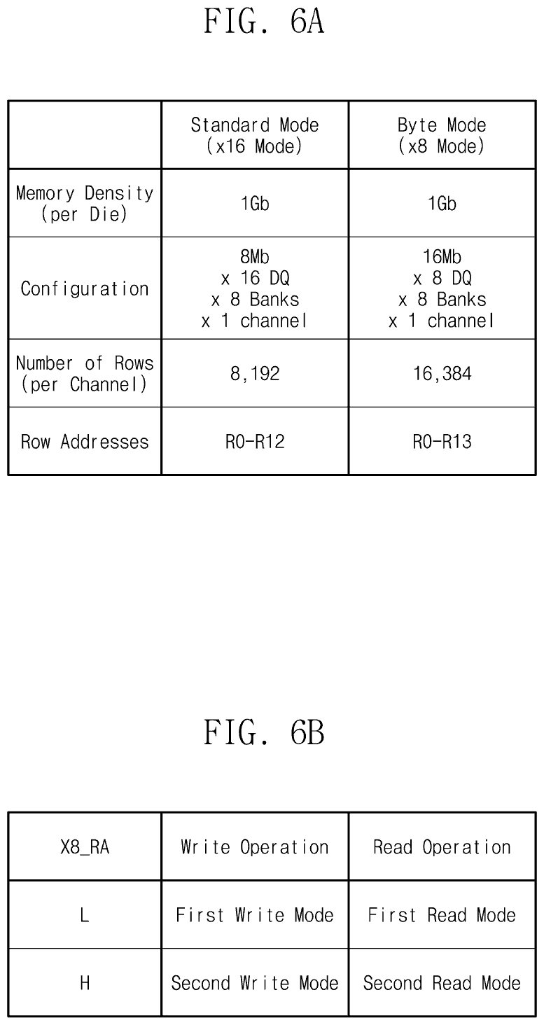

FIGS. 6A and 6B are diagrams for describing an expanded address value of FIG. 3.

As described with reference to FIG. 3, the expanded address value (e.g., the expanded address value X8_RA) may indicate that a semiconductor memory device (e.g., 300 of FIG. 3) operates in one of the first write mode and the second write mode. In the byte mode, when the semiconductor memory device 300 is configured to use the plurality of first data pins D1 pins<7:0>, the first write mode may refer to an operation mode in which write data received through the plurality of first data pins DQ pins<7:0> are written in the first storage region SR1, and the second write mode may refer to an operation mode in which the write data are written in the second storage region SR2. The first storage region SR1 and the second storage region SR2 are the same as those described with reference to FIG. 1 in association with the standard mode and the byte mode.

Referring to FIG. 6A, when a semiconductor memory device having, for example, a memory density of 1 Gb per die is implemented to operate in the standard mode or the byte mode, a configuration, the number of rows, and address bits indicating row addresses are illustrated for each semiconductor memory device.

For example, referring to the configuration of each semiconductor memory device, the data input/output may be performed through 16 data pins (e.g., ×16 DQ) in each semiconductor memory device, in the standard mode, and the data input/output may be performed through 8 data pins (e.g., ×8 DQ) in each semiconductor memory device, in the byte mode.

For example, referring to the number of rows and the address bits of each semiconductor memory device, the semiconductor memory device implemented to operate in the standard mode may include 8,192 rows, and the semiconductor memory device implemented to operate in the byte mode may include 16,384.

For example, to access the rows of the semiconductor memory device implemented to operate in the standard mode, the address bits may use a total of 13 bits from R0 to R12; to access the rows of the semiconductor memory device implemented to operate in the byte mode, the address bits may use a total of 14 bits from R0 to R13.

In an example embodiment, the expanded address value may be, for example, “R13”.

Referring to FIG. 6B, the expanded address value X8_RA may have one of the first logic level (e.g., logic high “H”) and the second logic level (e.g., logic low “L”).

In an example embodiment, when the expanded address value X8_RA has the first logic level, the semiconductor memory device may operate in the second write mode or the second read mode. When the expanded address value X8_RA has the second logic level, the semiconductor memory device may operate in the first write mode and the first read mode. As described with reference to FIGS. 1 and 3, in the byte mode, for example, when the semiconductor memory device 300 is configured to use the plurality of first data pins DQ pins<7:0>, the first write mode may refer to an operation mode in which write data received through the plurality of first data pins DQ pins<7:0> are written in the first storage region SR1, and the second write mode may refer to an operation mode in which the write data are written in the second storage region SR2.

In an example embodiment, the first read mode may be similar to the first write mode, and the second read mode may be similar to the second write mode. In the byte mode, for example, when the semiconductor memory device 300 is configured to use the plurality of first data pins DQ pins<7:0>, the first read mode may refer to a read mode of reading data from the first storage region SR1 through the plurality of first data pins DQ pins<7:0>, and the second read mode may refer to a read mode of reading data from the second storage region SR2 through the plurality of first data pins DQ pins<7:0>.

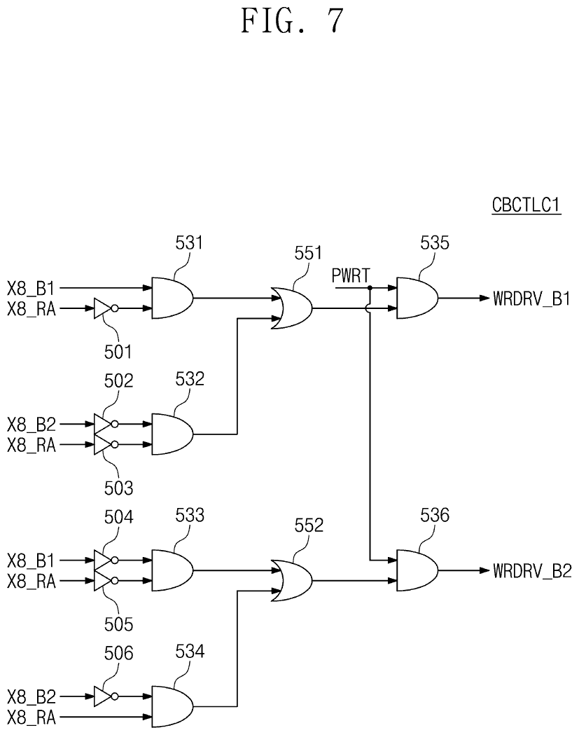

FIG. 7 is a diagram illustrating an example embodiment of a center-bus control circuit of FIG. 3.

Referring to FIGS. 3 and 7, the center-bus control circuit CBCTLC1 may include inverts 501, 502, 503, 504, 505, and 506, AND gates 531, 532, 533, 534, 535, and 536, and OR gates 551 and 552.

The center-bus control circuit CBCTLC1 may generate the control signals WRDRV_B1 and WRDRV_B2 based on the setting signals X8_B1 and X8_B2 and the expanded address value X8_RA.

In an example embodiment, when the first setting signal X8_B1 has the first logic level (e.g., logic high “H”) and the expanded address value X8_RA has the second logic level (e.g., logic low “L”) (e.g., when a plurality of first data pins (e.g., DQ pins<7:0> of FIG. 3) of a semiconductor memory device are used for a data input/output in the byte mode and the semiconductor memory device operates in the first write mode), the inverter 501 and the AND gate 531 may output an operation result with the first logic level to the OR gate 551. In this case, the inverter 501 and the AND gate 531 may contribute that the control signal WRDRV_B1 has the first logic level.

In an example embodiment, when the second setting signal X8_B2 has the second logic level and the expanded address value X8_RA has the first logic level (e.g., when the plurality of first data pins of a semiconductor memory device are used for a data input/output in the byte mode and the semiconductor memory device operates in the second write mode), the inverter 506 and the AND gate 534 may output an operation result with the first logic level to the OR gate 552. In this case, the inverter 506 and the AND gate 534 may contribute that the control signal WRDRV_B2 has the first logic level.

In an example embodiment, when the semiconductor memory device operates in the standard mode, the inverters 502 and 503 and the AND gate 532 may contribute that the control signal WRDRV_B1 has the first logic level, and the inverters 504 and 505 and the AND gate 533 may contribute that the control signal WRDRV_B2 has the first logic level.

In an example embodiment, when the write strobe signal PWRT has the first logic level, the operation results of the OR gates 551 and 552 may be output as operation results of the AND gates 535 and 536, and the operation results of the AND gates 535 and 536 may be output as the control signals WRDRV_B1 and WRDRV_B2. As described with reference to FIG. 4, the control signal WRDRV_B1 may enable the first center write driver 403 such that the write data are output, and the control signal WRDRV_B2 may enable the second center write driver 407 such that the write data are output.

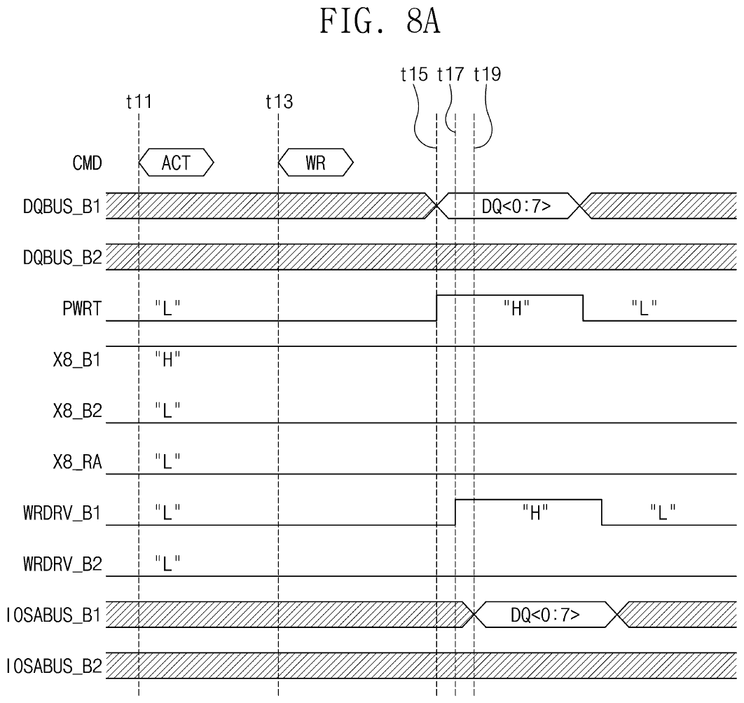

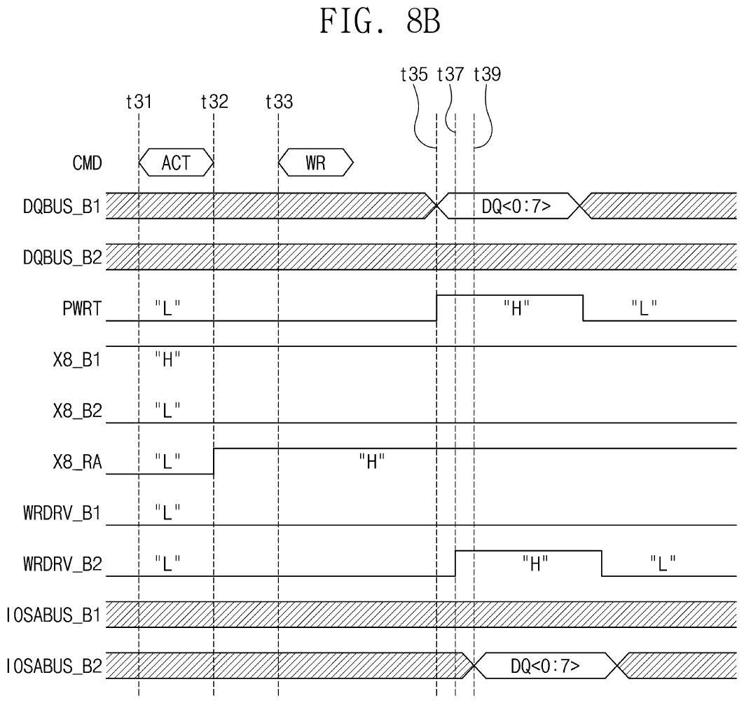

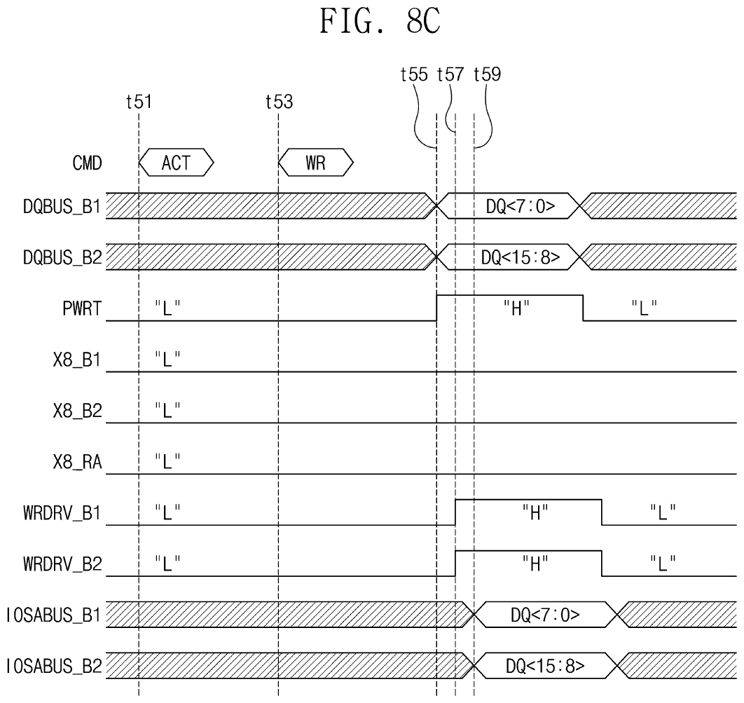

FIGS. 8A, 8B, and 8C are timing diagrams for describing an operation of a semiconductor memory device of FIG. 3.

In FIGS. 8A, 8B, and 8C, a semiconductor memory device (e.g., 300 of FIG. 3) may perform the write operation such that write data are written in a memory cell array (e.g., MCA of FIG. 3). As described with reference to FIGS. 3 and 4, the semiconductor memory device may operate in the standard mode or the byte mode and may write the write data in the first write mode or the second write mode. FIG. 8A shows the case where the semiconductor memory device operates in the byte mode, that is, the first write mode. FIG. 8B shows the case where the semiconductor memory device operates in the byte mode, that is, the second write mode. FIG. 8C shows the case where the semiconductor memory device operates in the standard mode.

Referring to FIG. 8A, points in times t11, t13, t15, t17, and t19 which sequentially progress are illustrated, the first setting signal X8_B1 may have the first logic level (e.g., logic high “H”), and the second setting signal X8_B2 and the expanded address value X8_RA may have the second logic level (e.g., logic low “L”). The command signal CMD including an active signal ACT may be received at t11, and the command signal CMD including a write command WR may be received at t13. At t15, the write data DQ<7:0> may be output from a first global write circuit, and the write strobe signal PWRT may transition from the second logic level to the first logic level. At t17, the control signal WRDRV_B1 may transition from the second logic level to the first logic level. At t19, a first center write buffer may output the write data to a first local write circuit (e.g., the first local write circuit LWC1) based on the control signal WRDRV_B1.

Referring to FIG. 8B, points in times t31, t32, t33, t35, t37, and t39 which sequentially progress are illustrated, the first setting signal X8_B1 may have the first logic level, and the second setting signal X8_B2 and the expanded address value X8_RA may have the second logic level. The command signal CMD including the active signal ACT may be received at t31, and the command signal CMD including the write command WR may be received at t33. The active signal ACT may include the expanded address value X8_RA; at t32, the expanded address value X8_RA may transition from the second logic level to the first logic level. At t35, the write data DQ<7:0> may be output from the first global write circuit, and the write strobe signal PWRT may transition from the second logic level to the first logic level. At t37, the control signal WRDRV_B2 may transition from the second logic level to the first logic level. At t39, a second center write buffer may output the write data to a second local write circuit (e.g., the second local write circuit LWC2) based on the control signal WRDRV_B2.

Referring to FIG. 8C, points in times t51, t53, t55, t57, and t59 which sequentially progress are illustrated, the first setting signal X8_B1, the second setting signal X8_B2, and the expanded address value X8_RA may have the second logic level. The command signal CMD including the active signal ACT may be received at t51, and the command signal CMD including the write command WR may be received at t53. At t55, the write data DQ<7:0> may be output from the first global write circuit (e.g., the first global write circuit GWC1), the write data DQ<15:8> may be output from the second global write circuit (e.g., the second global write circuit GWC2), and the write strobe signal PWRT may transition from the second logic level to the first logic level. At t57, the control signals WRDRV_B1 and WRDRV_B2 may transition from the second logic level to the first logic level. At t59, the first center write buffer may output the write data to the first local write circuit based on the control signal WRDRV_B1; at t59, the second center write buffer may output the write data to the second local write circuit based on the control signal WRDRV_B2.

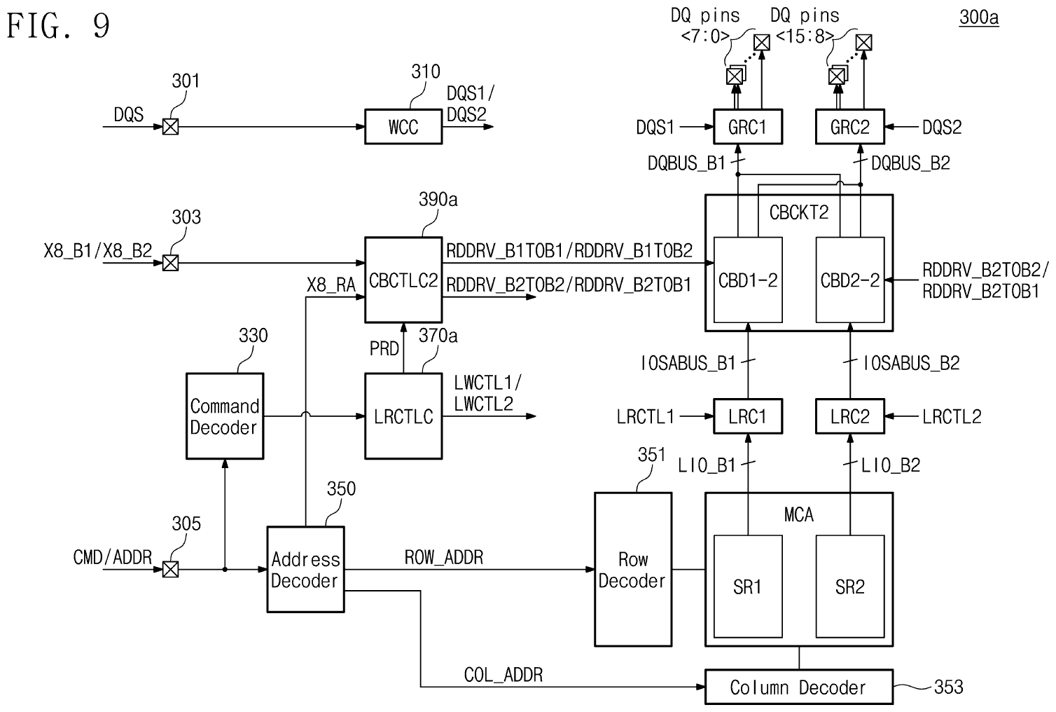

FIG. 9 is a block diagram illustrating a semiconductor memory device according to some embodiments of the present disclosure.

Referring to FIG. 9, a semiconductor memory device 300a may correspond to the semiconductor memory device 100 of FIG. 1. The semiconductor memory device 300a may include the memory cell array MCA including the first storage region SR1 and the second storage region SR2, the plurality of first data pins DQ pins<7:0>, the plurality of second data pins DQ pins<15:8>, a first global read circuit GRC1, a second global read circuit GRC2, the center-bus circuit CBCKT2, a first local read circuit LRC1, and a second local read circuit LRC2, and components which are marked by reference numerals/signs the same as or similar to those of the components included in the semiconductor memory device 100 may perform the same or similar functions. For example, the semiconductor memory device 300a may correspond to the semiconductor memory device 100 which performs the “read operation”.

The semiconductor memory device 300a may further include the data strobe pin 301, the byte mode setting pin 303, the command/address pin 305, the write clock circuit 310, the command decoder 330, the address decoder 350, the row decoder 351, the column decoder 353, a center-bus control circuit (CBCTLC2) 390a, a local read control circuit (LRCTLC) 370a. Because the semiconductor memory device 300a is the same as the semiconductor memory device 300 except that the semiconductor memory device 300a performs the read operation, components of FIG. 9, which are marked by reference numerals/signs the same as or similar to those of FIG. 3, may perform the same or similar functions. Thus, additional description may be omitted to avoid redundancy.

The center-bus control circuit 390a may generate a center-bus control signal based on the byte mode setting signal and the address signal ADDR and may control the center-bus circuit CBCKT2 based on the center-bus control signal. For example, the center-bus control circuit 390a may provide control signals RDDRV_B1TOB1, RDDRV_B1TOB2, RDDRV_B2TOB2, and RDDRV_B2TOB1 to the center-bus circuit CBCKT2, based on the first setting signal X8_B1, the second setting signal X8_B2, the expanded address value X8_RA, and a read strobe signal PRD. The center-bus circuit CBCKT2 may include a first center-bus driver CBD1-2 and a second center-bus driver CBD2-2, the control signals RDDRV_B1TOB1 and RDDRV_B1TOB2 may be provided to the first center-bus driver CBD1-2, and the control signals RDDRV_B2TOB2 and RDDRV_B2TOB1 may be provided to the second center-bus driver CBD2-2.

In an example embodiment, in the embodiment illustrated in FIG. 9, in the byte mode of the semiconductor memory device 300a, the plurality of first data pins DQ pins<7:0> may output read data. In this case, the plurality of second data pins DQ pins<15:8> may be unused. However, the scope of the present disclosure is not limited thereto. In another example embodiment, in the byte mode of the semiconductor memory device 300a, the plurality of second data pins DQ pins<15:8> may output read data. In this case, the plurality of first data pins DQ pins<7:0> may be unused.

In an example embodiment, in the byte mode of the semiconductor memory device 300a, When the semiconductor memory device 300a is configured to use the plurality of first data pins DQ pins<7:0>, the first global read circuit GRC1 may be (electrically) connected to the plurality of first data pins DQ pins<7:0> and may provide the read data. The center-bus circuit CBCKT2 may be (electrically) connected to the first global read circuit GRC1. In the first read mode of reading the read data from the first storage region SR1, the center-bus circuit CBCKT2 may provide the read data to the third connection terminal; in the second read mode of reading the read data from the second storage region SR2, the center-bus circuit CBCKT2 may provide the read data to the third connection terminal.

In an embodiment, the first global read circuit GRC1 may output the read data provided through the third connection terminal to the plurality of first data pins DQ pins<7:0>.

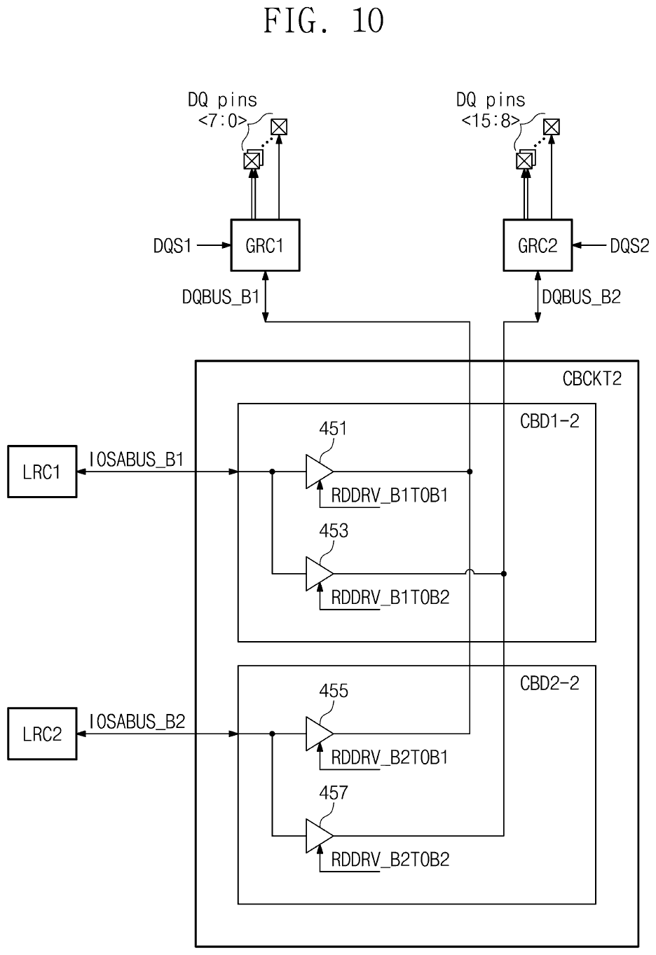

FIG. 10 is a block diagram for describing an example embodiment of components of a semiconductor memory device including a center-bus circuit of FIG. 9.

For convenience of description, only some of the components of the semiconductor memory device 300a of FIG. 9 are illustrated in FIG. 10. In FIGS. 9 and 10, components which are marked by the same reference numerals/signs may perform the same or similar functions.

Referring to FIGS. 9 and 10, the center-bus circuit CBCKT2 may include the first center-bus driver CBD1-2 and the second center-bus driver CBD2-2.

In an example embodiment, in the byte mode of the semiconductor memory device 300a, when the semiconductor memory device 300a is configured to use the plurality of first data pins DQ pins<7:0>, in the first read mode, the first center-bus driver CBD1-2 may receive data from the first local read circuit LRC1 and may output the received data to the first global read circuit GRC1. In the second read mode, the second center-bus driver CBD2-2 may receive data from the second local read circuit LRC2 and may output the received data to the first global read circuit GRC1. In the byte mode of the semiconductor memory device 300a, when the semiconductor memory device 300a is configured to use the plurality of second data pins DQ pins<15:8>, in the first write mode, the second center-bus driver CBD202 may receive data from the second local read circuit LRC2 and may output the received data to the second global read circuit GRC2. In the second read mode, the first center-bus driver CBD1-2 may receive data from the first local read circuit LRC1 and may output the received data to the second global read circuit GRC2.

In an example embodiment, the first center-bus driver CBD1-2 may include a first center read buffer 451 and a second center read buffer 453. In the byte mode, for example, when the semiconductor memory device 300a is configured to use the plurality of first data pins DQ pins<7:0>, in the first read mode, the first center read buffer 451 may output the read data transferred from the first local read circuit LRC1 to the first global read circuit GRC1. The second center read buffer 453 may be unused in an embodiment where, in the byte mode, the plurality of first data pins DQ pins<7:0> are only used and the plurality of second data pins DQ pins<15:8> are unused. The first center read buffer 451 may output the read data based on the control signal RDDRV_B1TOB1, and the second center read buffer 453 may output the read data based on the control signal RDDRV_B1TOB2.

In an example embodiment, the second center-bus driver CBD2-2 may include a third center read buffer 455 and a fourth center read buffer 457. In the byte mode, for example, when the semiconductor memory device 300a is configured to use the plurality of first data pins DQ pins<7:0>, in the second read mode, the third center read buffer 455 may output the read data transferred from the second local read circuit LRC2 to the first global read circuit GRC1. The fourth center read buffer 457 may be unused in an embodiment where, in the byte mode, the plurality of first data pins DQ pins<7:0> are only used and the plurality of second data pins DQ pins<15:8> are unused. The third center read buffer 455 may output the read data based on the control signal RDDRV_B2TOB1, and the fourth center read buffer 457 may output the read data based on the control signal RDDRV_B2TOB2.

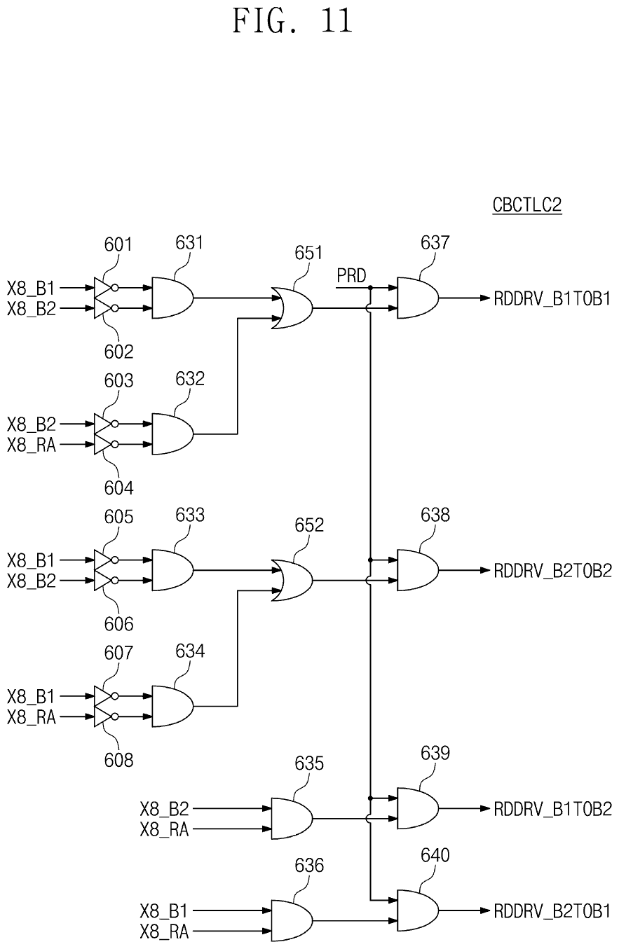

FIG. 11 is a diagram illustrating an example embodiment of a center-bus control circuit of FIG. 9.

Referring to FIGS. 9 and 11, the center-bus control circuit CBCTLC2 may include inverts 601, 602, 603, 604, 605, 606, 607, and 608, AND gates 631, 632, 633, 634, 635, 636, 637, 638, 639, and 640, and OR gates 651 and 652.

The center-bus control circuit CBCTLC2 may generate the control signals RDDRV_B1TOB1, RDDRV_B2TOB2, RDDRV_B1TOB2, and RDDRV_B2TOB1 based on the setting signals X8_B1 and X8_B2 and the expanded address value X8_RA.

In an example embodiment, when both the second setting signal X8_B2 and the expanded address value X8_RA have the second logic level (e.g., logic low “L”) (e.g., when a plurality of first data pins (e.g., DQ pins<7:0> of FIG. 3) of a semiconductor memory device are used for a data input/output in the byte mode and the semiconductor memory device operates in the first read mode), the inverters 603 and 604 and the AND gate 632 may output an operation result with the first logic level to the OR gate 651. In this case, the inverters 603 and 604 and the AND gate 632 may contribute that the control signal RDDRV_B1TOB1 has the first logic level.

In an example embodiment, when both the first setting signal X8_B1 and the expanded address value X8_RA have the second logic level (e.g., when a plurality of second data pins (e.g., DQ pins<15:8> of FIG. 3) of the semiconductor memory device are used for a data input/output in the byte mode and the semiconductor memory device operates in the second read mode, the inverters 607 and 608 and the AND gate 634 may output an operation result with the first logic level to the OR gate 652. In this case, the inverters 607 and 608 and the AND gate 634 may contribute that the control signal RDDRV_B2TOB2 has the first logic level.

In an example embodiment, when both the second setting signal X8_B2 and the expanded address value X8_RA have the first logic level (e.g., when the plurality of second data pins of the semiconductor memory device are used for a data input/output in the byte mode and the semiconductor memory device operates in the second read mode), the AND gate 635 may output an operation result with the first logic level to the AND gate 639. In this case, the AND gate 635 may contribute that the control signal RDDRV_B1TOB2 has the first logic level.

In an example embodiment, when both the first setting signal X8_B1 and the expanded address value X8_RA have the first logic level (e.g., when the plurality of first data pins of the semiconductor memory device are used for a data input/output in the byte mode and the semiconductor memory device operates in the second read mode), the AND gate 636 may output an operation result with the first logic level to the AND gate 640. In this case, the AND gate 636 may contribute that the control signal RDDRV_B2TOB1 has the first logic level.

In an example embodiment, when the semiconductor memory device operates in the standard mode, the inverters 603 and 604 and the AND gate 632 may contribute that the control signal RDDRV_B1TOB1 has the first logic level, and the inverters 605 and 606 and the AND gate 633 may contribute that the control signal RDDRV_B2TOB2 has the first logic level.

In an example embodiment, when the read strobe signal PRD has the first logic level, the operation results of the OR gates 651 and 652 and the operation results of the AND gates 635 and 636 may be output as operation results of the AND gates 637, 638, 639, and 640, and the operation results of the AND gates 637, 638, 639 and 640 may be output as the control signals RDDRV_B1TOB1, RDDRV_B2TOB2, RDDRV_B1TOB2, and RDDRV_B2TOB1. As described with reference to FIG. 10, the control signal RDDRV_B1TOB1 may enable the first center read buffer 451 such that the read data are output, and the control signal RDDRV_B2TOB2 may enable the fourth center read buffer 457 such that the read data are output. The control signal RDDRV_B1TOB2 may enable the second center read buffer 453 such that the read data are output, and the control signal RDDRV_B2TOB1 may enable the third center read buffer 455 such that the read data are output.

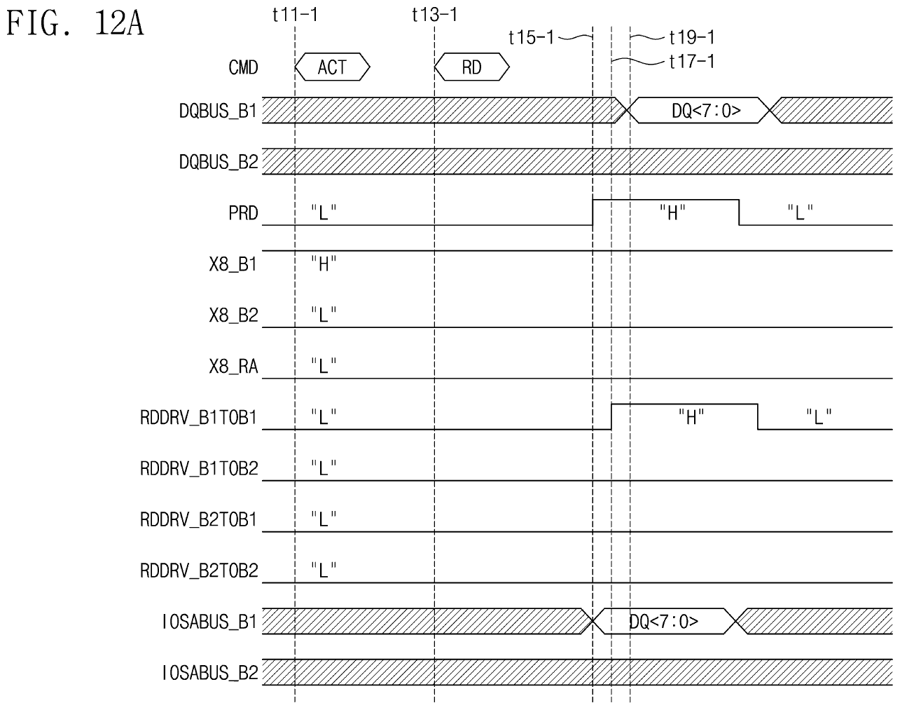

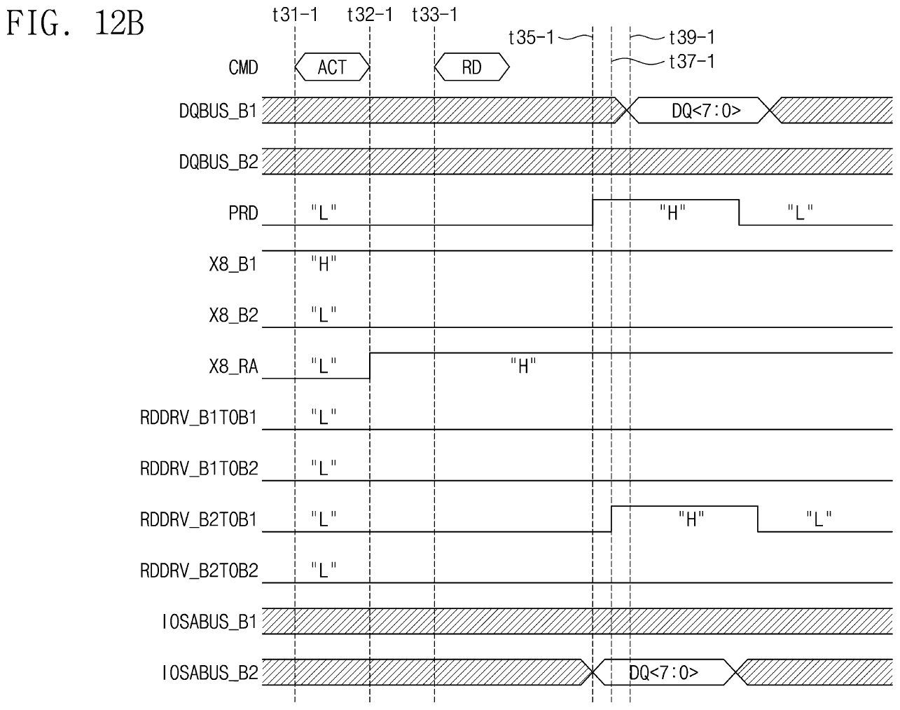

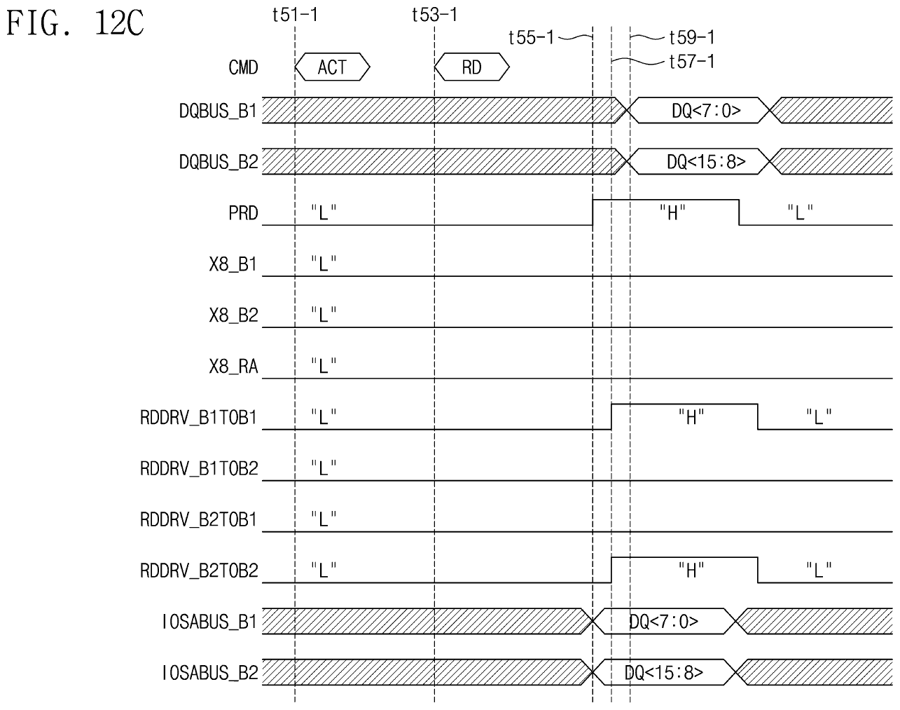

FIGS. 12A, 12B, and 12C are timing diagrams for describing an operation of a semiconductor memory device of FIG. 9.

In FIGS. 12A, 12B, and 12C, a semiconductor memory device (e.g., 300a of FIG. 9) may perform the read operation in which read data are read from a memory cell array (e.g., MCA of FIG. 9). As described with reference to FIGS. 3 and 4, the semiconductor memory device may operate in the standard mode or the byte mode and may output the read data in the first read mode or the second read mode. FIG. 12A shows the case where the semiconductor memory device operates in the byte mode, that is, the first read mode. FIG. 12B shows the case where the semiconductor memory device operates in the byte mode, that is, the second read mode. FIG. 12C shows the case where the semiconductor memory device operates in the standard mode.

Referring to FIG. 12A, points in times t11-1, t13-1, t15-1, t17-1, and t19-1 which sequentially progress are illustrated, the first setting signal X8_B1 may have the first logic level, and the second setting signal X8_B2 and the expanded address value X8_RA may have the second logic level. The command signal CMD including the active signal ACT may be received at t11-1, and the command signal CMD including a read command RD may be received at t13-1. At t15-1, the read data DQ<7:0> may be output from the first local read circuit (e.g., the first local read circuit LRC1), and the read strobe signal PRD may transition from the second logic level to the first logic level. At t17-1, the control signal RDDRV_B1TOB1 may transition from the second logic level to the first logic level. At t19-1, a first center read buffer (e.g., the first center read buffer 451) may output the read data to a first global read circuit (e.g., the first global read circuit GRC1) based on the control signal RDDRV_B1TOB1.

Referring to FIG. 12B, points in times t31-1, t32-1, t33-1, t35-1, t37-1, and t39-1 which sequentially progress are illustrated, the first setting signal X8_B1 may have the first logic level, and the second setting signal X8_B2 and the expanded address value X8_RA may have the second logic level. The command signal CMD including the active signal ACT may be received at t31-1, and the command signal CMD including the read command RD may be received at t33-1. The active signal ACT may include the expanded address value X8_RA; at t32-1, the expanded address value X8_RA may transition from the second logic level to the first logic level. At t35-1, the read data DQ<7:0> may be output from the second local read circuit (e.g., the second local read circuit LRC2), and the read strobe signal PRD may transition from the second logic level to the first logic level. At t37-1, the control signal RDDRV_B2TOB1 may transition from the second logic level to the first logic level. At t39-1, a third center read buffer (e.g., the third center read buffer 455) may output the read data to the first global read circuit (e.g., the first global read circuit GRC1) based on the control signal RDDRV_B2TOB1.

Referring to FIG. 12C, points in times t51-1, t53-1, t55-1, t57-1, and t59-1 which sequentially progress are illustrated, the first setting signal X8_B1, the second setting signal X8_B2, and the expanded address value X8_RA may have the second logic level. The command signal CMD including the active signal ACT may be received at t51-1, and the command signal CMD including the read command RD may be received at t53-1. At t55-1, the read data DQ<7:0> may be output from the first local read circuit (e.g., the first local read circuit LRC1), the read data DQ<15:8> may be output from the second local read circuit (e.g., the second local read circuit LRC2), and the read strobe signal PRD may transition from the second logic level to the first logic level. At t57-1, the control signals RDDRV_B1TOB1 and RDDRV_B2TOB2 may transition from the second logic level to the first logic level. The first center read buffer (e.g., the first center read buffer 451) may output the read data to the first global read circuit (e.g., the first global read circuit GRC1) based on the control signal RDDRV_B1TOB1; the fourth center read buffer (e.g., the fourth center read buffer 457) may output the read data to a second global read circuit (e.g., the second global read circuit GRC2) based on the control signal RDDRV_B2TOB2.

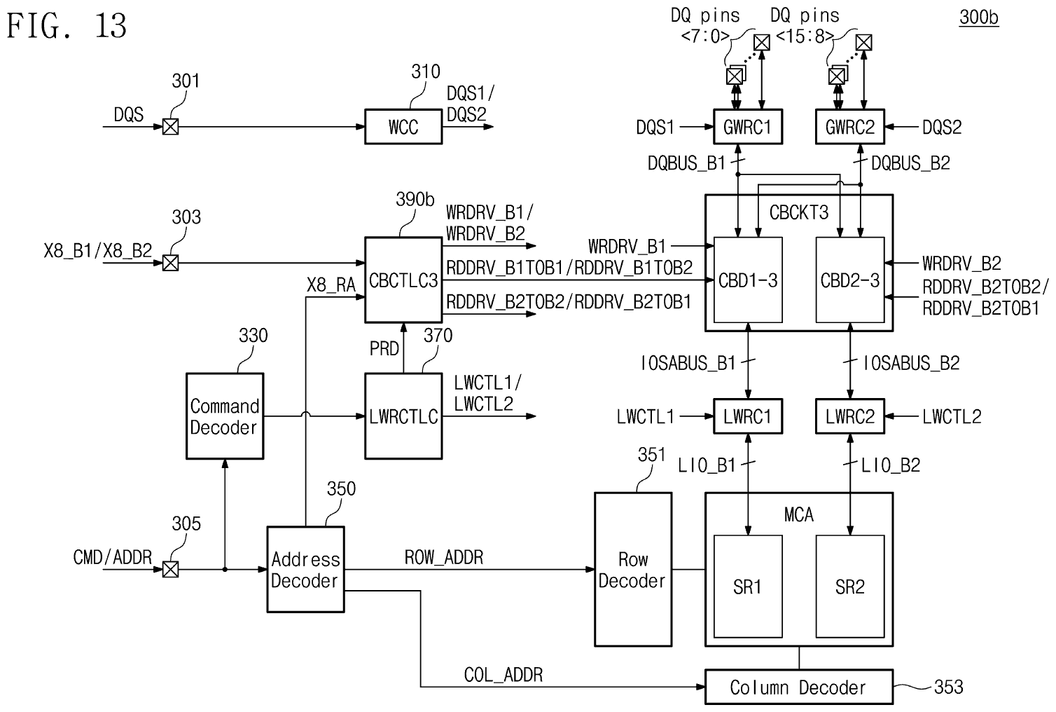

FIG. 13 is a block diagram illustrating a semiconductor memory device according to some embodiments of the present disclosure.

Referring to FIG. 13, a semiconductor memory device 300b may correspond to the semiconductor memory device 100 of FIG. 1 and may perform both the “write operation” of the semiconductor memory device 300 of FIG. 3 and the “read operation” of the semiconductor memory device 300a of FIG. 9. The semiconductor memory device 300b may include the memory cell array MCA including the first storage region SR1 and the second storage region SR2, the plurality of first data pins DQ pins<7:0>, the plurality of second data pins DQ pins<15:8>, a first global write/read circuit GWRC1, a second global write/read circuit GWRC2, the center-bus circuit CBCKT3, a first local write/read circuit LWRC1, and a second local write/read circuit LWRC2, and components which are marked by reference numerals/signs the same as or similar to those of the components included in the semiconductor memory devices 300 and 300a may perform the same or similar functions. Thus, additional description may be omitted to avoid redundancy.

In an example embodiment, the memory cell array MCA may include the first storage region SR1 and the second storage region SR2. In the embodiment illustrated in FIG. 13, the plurality of first data pins DQ pins<7:0> may be used in the byte mode of the semiconductor memory device 300b. In this case, the plurality of second data pins DQ pins<15:8> may be unused in the byte mode. However, the scope of the present disclosure is not limited thereto. In another example embodiment, in the byte mode of the semiconductor memory device 300b, the plurality of second data pins DQ pins<15:8> may be used. In this case, the plurality of first data pins DQ pins<7:0> may be unused in the byte mode.

In an example embodiment, the center-bus circuit CBCKT3 may provide a path for data transmission between the plurality of first data pins DQ pins<7:0> and the first storage region SR1 in a first write/read mode in which there is performed the write or read operation on the first storage region SR1 and a path for data transmission between the plurality of first data pins DQ pins<7:0> and the second storage region SR2 in a second write/read mode in which there is performed the write or read operation on the second storage region SR2.

In an example embodiment, the center-bus circuit CBCKT3 may include one multiplexer and one center write buffer for performing the write operation on the first storage region SR1 in the first write/read mode and may include another multiplexer and another center write buffer for performing the write operation on the second storage region SR2 in the second write/read mode.

In an example embodiment, the center-bus circuit CBCKT3 may include two center read buffers for performing the read operation on the first storage region SR1 in the first write/read mode and may include (the other) two center read buffers for performing the read operation on the second storage region SR2 in the second write/read mode.

A center-bus control circuit 390b may perform all the functions of the center-bus control circuit 390 of FIG. 3 and the center-bus control circuit 390a of FIG. 9. The center-bus circuit CBCKT3 may include a first center-bus driver CBD1-3 and a second center-bus driver CBD2-3, the control signals WRDRV_B1, RDDRV_B1TOB1, and RDDRV_B1TOB2 may be provided to the first center-bus driver CBD1-3, and the control signals WRDRV_B2, RDDRV_B2TOB2, and RDDRV_B2TOB1 may be provided to the second center-bus driver CBD2-3.

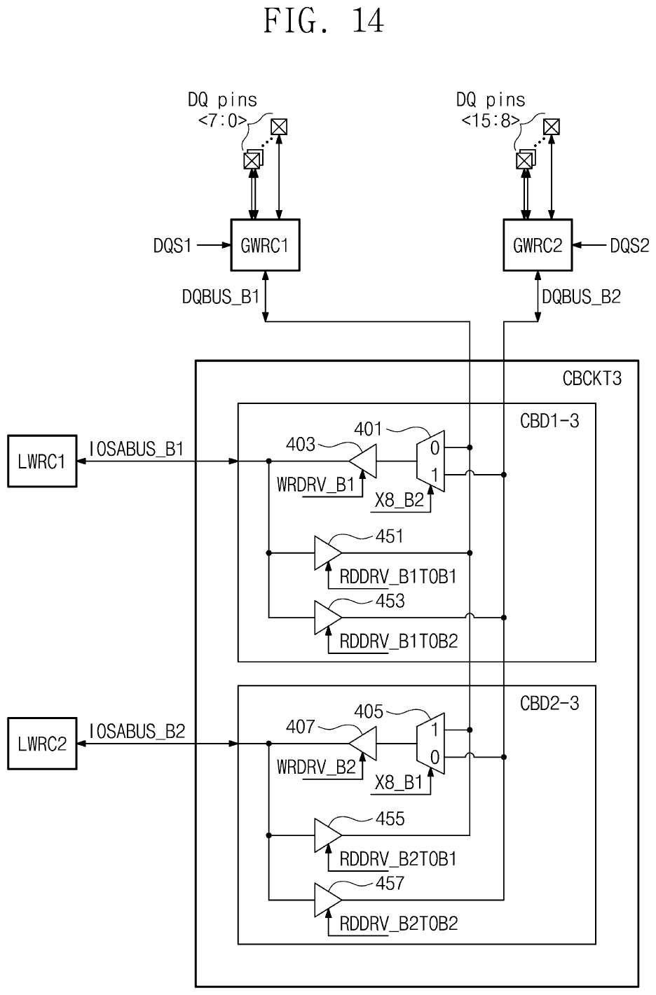

FIG. 14 is a block diagram for describing an example embodiment of components of a semiconductor memory device including a center-bus circuit of FIG. 13.

For convenience of description, only some of the components of the semiconductor memory device 300b of FIG. 13 are illustrated in FIG. 14. In FIGS. 13 and 14, components which are marked by the same reference numerals/signs may perform the same or similar functions.

The center-bus circuit CBCKT3 may perform all the functions of the center-bus circuit CBCKT1 of FIG. 3 and the center-bus circuit CBCKT2 of FIG. 9. Thus, additional description may be omitted to avoid redundancy.

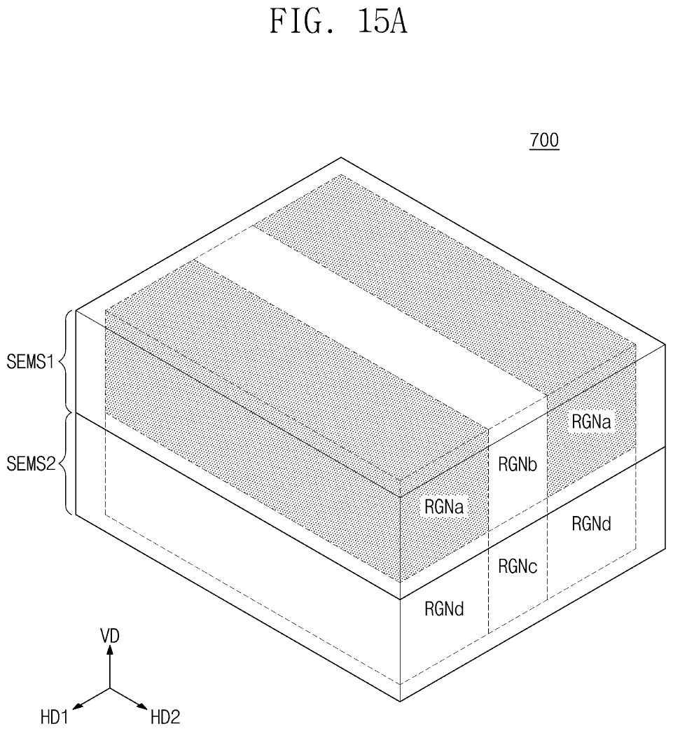

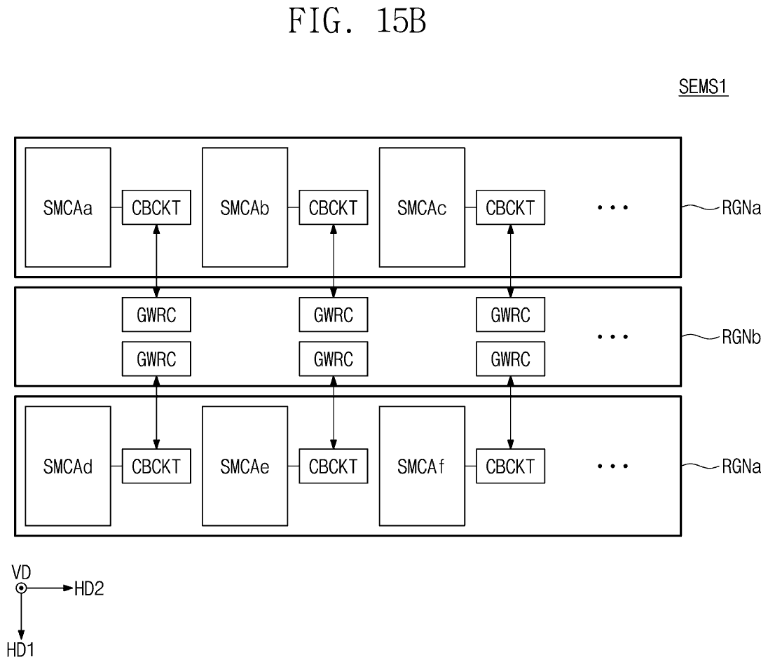

FIGS. 15A and 15B are diagrams for describing locations where center-bus circuits of FIGS. 3, 8, and 13 are disposed.

In FIGS. 15A and 15B, a vertical direction VD, a first horizontal direction HD1, and a second horizontal direction HD2 which are perpendicular to each other are illustrated.

Referring to FIG. 15A, a semiconductor memory device 700 may include a first semiconductor structure SEMS1 and a second semiconductor structure SEMS2. An example in which the second semiconductor structure SEMS2 is disposed under the first semiconductor structure SEMS1 is illustrated in FIG. 15A, but this is only an example. In another embodiment, the first semiconductor structure SEMS1 may be disposed under the second semiconductor structure SEMS2.

In an example embodiment, the semiconductor memory device 700 may have a cell on periphery (COP) structure in which peripheral circuits are disposed under memory cells. As the COP structure is applied to the semiconductor memory device 100, the storage capacity of the semiconductor memory device 100 may increase, and the degree of integration of the semiconductor memory device 100 may become higher, the utilization of space of the semiconductor memory device 100 may be improved, and the costs for manufacturing the semiconductor memory device 100 may be reduced.

The semiconductor memory device 700 may include regions RGNa, RGNb, RGNc, and RGNd therein. Each of the regions RGNa and RGNb may be a region in the first semiconductor structure SEMS1, and each of the regions RGNc and RGNd may be a region in the second semiconductor structure SEMS2.

In an example embodiment, each of the regions RGNa, RGNb, RGNc, and RGNd may include one or more regions as illustrated in FIG. 15A. For example, because a plurality of memory cells may be able to be disposed in the region RGNa, the region RGNa may be referred to as a “memory cell array region”, and the region RGNd may be referred to as a “lower side of the memory cell array region”. For example, because the region RGNb may be able to be between one memory cell array region and another memory cell array region (in a horizontal direction (e.g., the first horizontal direction HD1)) and the region RGNc may be able to be disposed under the region RGNb, the regions RGNb and RGNc may be referred to as a “middle region”, the region RGNb may be referred to as an “upper middle region”, and the region RGNc may be referred to as a “lower middle region”.

Referring to FIG. 15B, the first semiconductor structure SEMS1 may include the regions RGNa and RGNb. Sub-memory cell arrays SMCAa, SMCAb, SMCAc, SMCAd, SMCAe, and SMCAf and center-bus circuits CBCKTs may be disposed in the regions RGNa (the memory cell array region RGNa), and global write/read circuits GWRCs may be disposed in the region RGNb (the upper middle region RGNb). However, this is only an example.

In an example embodiment, the sub-memory cell arrays SMCAa, SMCAb, and SMCAc may be disposed at the first row of a semiconductor memory device, and the sub-memory cell arrays SMCAd, SMCAe, and SMCAf may be disposed at the second row of the semiconductor memory device.

In an example embodiment, the center-bus circuits CBCKTs may be disposed between the sub-memory cell arrays SMCAa, SMCAb, and SMCAc (in the second horizontal direction HD2) belonging to the first row and may be disposed between the sub-memory cell arrays SMCAd, SMCAe, and SMCAf (in the second horizontal direction HD2) belonging to the second row. However, this is only an example.

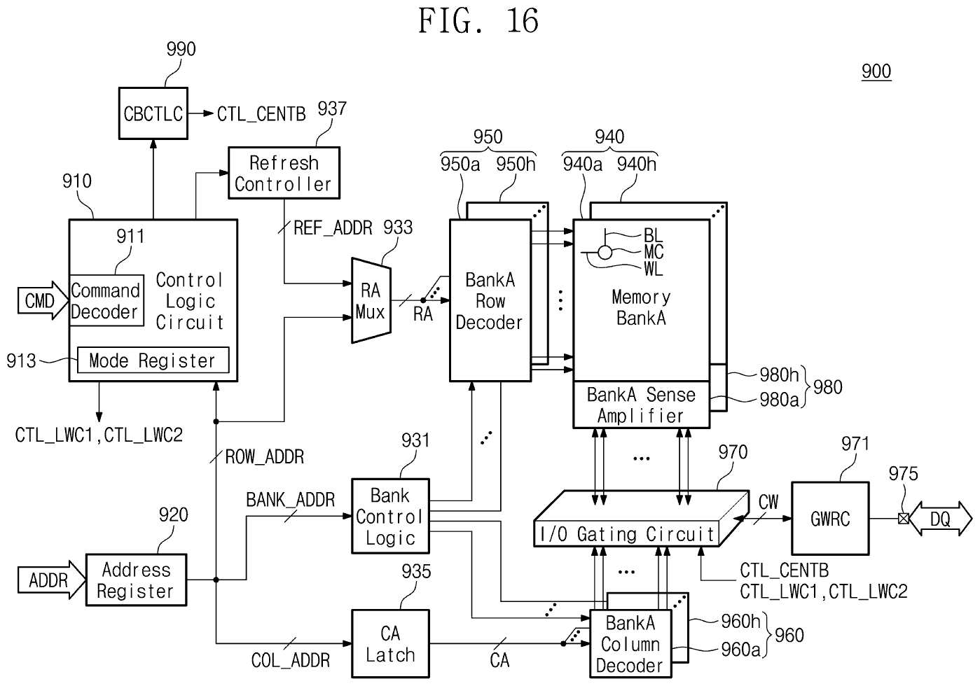

FIG. 16 is a block diagram illustrating a volatile memory device according to some embodiments of the present disclosure.

Referring to FIG. 16, a memory device 900 may include a control logic circuit 910, an address register 920, bank control logic 931, a row address multiplexer 933, a column address latch 935, a refresh controller 937, a bank array 940, a row decoder 950, a column decoder 960, an input/output gating circuit 970, a global write/read circuit 971, a data input/output pad 975, a bitline sense amplifier set 980, and a center-bus control circuit 990. The control logic circuit 910 may include a command decoder 911 and a mode register 913. For example, the memory device 900 may be a volatile memory device. In particular, the memory device 900 may be a dynamic random access memory (DRAM).

The bank array 940 may include a plurality bank arrays 940a, 940b, 940c, 940d, 940e, 940f, 940g, and 940h. The row decoder 950 may include a plurality of bank row decoders 950a, 950b, 950c, 950d, 950e, 950f, 950g, and 950h respectively (electrically) connected to the plurality of bank arrays 940a, 940b, 940c, 940d, 940e, 940f, 940g, and 940h, the column decoder 960 may include a plurality of bank column decoders 960a, 960b, 960c, 960d, 960e, 960f, 960g, and 960h respectively (electrically) connected to the plurality of bank arrays 940a, 940b, 940c, 940d, 940e, 940f, 940g, and 940h, and the bitline sense amplifier set 980 may include a plurality of bank sense amplifiers 980a, 980b, 980c, 980d, 980e, 980f, 980g, and 980h respectively (electrically) connected to the plurality of bank arrays 940a, 940b, 940c, 940d, 940e, 940f, 940g, and 940h. The plurality of bank arrays 940a, 940b, 940c, 940d, 940e, 940f, 940g, and 940h, the plurality of bank row decoders 950a, 950b, 950c, 950d, 950e, 950f, 950g, and 950h, and the plurality of bank column decoders 960a, 960b, 960c, 960d, 960e, 960f, 960g, and 960h may constitute a plurality of banks. Each of the plurality of bank arrays 940a, 940b, 940c, 940d, 940e, 940f, 940g, and 940h may include a plurality of memory cells MC which are formed at intersections of a plurality of wordlines WLs and a plurality of bitlines BLs.

The address register 920 may receive an address ADDR including a bank address BANK_ADDR, a row address ROW_ADDR, and a column address COL_ADDR from a memory controller. The address register 920 may provide the bank address BANK_ADDR to the bank control logic 931, may provide the row address ROW_ADDR to the row decoder 950 through the row address multiplexer 933, and may provide the column address COL_ADDR to the column decoder 960 through the column address latch 935.

The bank control logic 931 may generate bank control signals in response to the bank address BANK_ADDR. The bank row decoders 950a, 950b, 950c, 950d, 950e, 950f, 950g, and 950h and the bank column decoders 960a, 960b, 960c, 960d, 960e, 960f, 960g, and 960h corresponding the bank address BANK_ADDR may be activated based on the bank control signals.

The refresh controller 937 may generate a refresh row address REF_ADDR which sequentially increases or decreases under control of the control logic circuit 910.

Activated bank column decoders among the plurality of bank column decoders 960a, 960b, 960c, 960d, 960e, 960f, 960g, and 960h may activate the bank sense amplifiers 980a, 980b, 980c, 980d, 980e, 980f, 980g, and 980h corresponding to the bank address BANK_ADDR, the row address ROW_ADDR, and the column address COL_ADDR by using the input/output gating circuit 970.

Data to be read from one of the plurality of bank arrays 940a, 940b, 940c, 940d, 940e, 940f, 940g, and 940h may be sensed by a bank sense amplifier (e.g., the bank sense amplifiers 980a, 980b, 980c, 980d, 980e, 980f, 980g, and 980h) corresponding to the one bank array, and the sensed data may be provided to the memory controller as the DQ signal through the global write/read circuit 971.

Data to be written in one of the plurality of bank arrays 940a, 940b, 940c, 940d, 940e, 940f, 940g, and 940h may be provided to the input/output gating circuit 970 through the global write/read circuit 971, and the input/output gating circuit 970 may write the data provided from the global write/read circuit 971 in the one bank array.

The control logic circuit 910 may control the operation of the memory device 900. For example, the control logic circuit 910 may generate control signals such that the memory device 900 performs the write operation or the read operation. The command decoder 911 may decode the command CMD received from the memory controller, and the mode register 913 may set an operation mode of the memory device 900. For example, the command decoder 911 may decode a write enable signal, a row address strobe signal, a column address strobe signal, a chip select signal, etc. and may generate the control signals corresponding to the command CMD.

In an example embodiment, the center-bus control circuit 990 may correspond to each of the center-bus control circuits CBCTLC1, CBCTLC2, and CBCTLC3 described with reference to FIGS. 3, 9, and 13, and the input/output gating circuit 970 may include the center-bus control circuits CBCTLC1, CBCTLC2, and CBCTLC3 described with reference to FIGS. 3, 9, and 13. The global write/read circuit 971 may correspond to the global write circuits GWC1 and GWC2, the global read circuits GRC1 and GRC2, and the global write/read circuits GWRC1 and GWRC2 described with reference to FIGS. 3, 9, and 13. Accordingly, the center-bus control circuit 990 may control the operations of the semiconductor memory device according to embodiments of the present disclosure by generating the center-bus control signal CTL_CENTB and the control signals CTL_LWC1 and CTL_LWC2 and controlling the input/output gating circuit 970 and the global write/read circuit 971 based on the center-bus control signal CTL_CENTB and the control signals CTL_LWC1 and CTL_LWC2 and may implement the byte mode of the semiconductor memory device by using the center-bus circuit, and thus, the complexity or area of the data input/output circuit may be reduced.

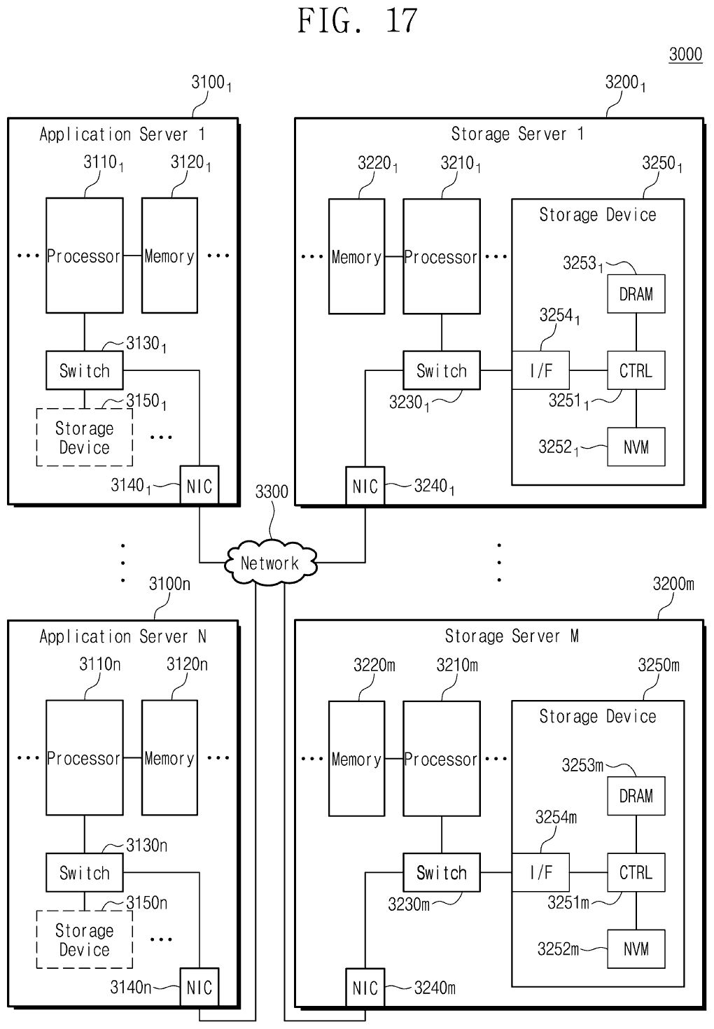

FIG. 17 is a diagram illustrating a data center including the memory system according to some embodiments of the present disclosure.

Referring to FIG. 17, the data center 3000 may be a facility that collects various types of pieces of data and provides services and be referred to as a data storage center. The data center 3000 may be a system for operating a search engine and a database, and may be a computing system used by companies, such as banks, or government agencies. The data center 3000 may include application servers 3100₁ to 3100n and storage servers 3200₁ to 3200m. The number of application servers 3100₁ to 3100n and the number of storage servers 3200₁ to 3200m may be variously selected according to embodiments. The number of application servers 3100₁ to 3100n may be different from the number of storage servers 3200₁ to 3200m.

The application server 3100₁ or the storage server 3200₁ may include at least one of processors 3110 and 3210 and memories 3120 and 3220. The storage server 3200₁ will now be described as an example. The processor 3210 may control all operations of the storage server 3200₁, access the memory 3220, and execute instructions and/or data loaded in the memory 3220. The memory 3220 may be a double-data-rate synchronous DRAM (DDR SDRAM), a high-bandwidth memory (HBM), a hybrid memory cube (HMC), a dual in-line memory module (DIMM), Optane DIMM, and/or a non-volatile DIMM (NVMDIMM). In some embodiments, the numbers of processors 3210 and memories 3220 included in the storage server 3200₁ may be variously selected. In an example embodiment, the processor 3210 and the memory 3220 may provide a processor-memory pair. In an example embodiment, the number of processors 3210 may be different from the number of memories 3220. The processor 3210 may include a single-core processor or a multi-core processor. The above description of the storage server 3200₁ may be similarly applied to the application server 3100₁. In some embodiments, the application server 3100₁ may not include a storage device 3150. The storage server 3200₁ may include at least one storage device 3250. The number of storage devices 3250 included in the storage server 3200₁ may be variously selected according to embodiments.

The application servers 3100₁ to 3100n may communicate with the storage servers 3200₁ to 3200m through a network 3300. The network 3300 may be implemented by using a fiber channel (FC) or Ethernet. In this case, the FC may be a medium used for relatively high-speed data transmission and use an optical switch with high performance and high availability. The storage servers 3200₁ to 3200m may be provided as file storages, block storages, or object storages according to an access method of the network 3300.

In an example embodiment, the network 3300 may be a storage-dedicated network, such as a storage area network (SAN). For example, the SAN may be an FC-SAN, which uses an FC network and is implemented according to an FC protocol (FCP). As another example, the SAN may be an Internet protocol (IP)-SAN, which uses a transmission control protocol (TCP)/IP network and is implemented according to a SCSI over TCP/IP or Internet SCSI (iSCSI) protocol. In another embodiment, the network 3300 may be a general network, such as a TCP/IP network. For example, the network 3300 may be implemented according to a protocol, such as FC over Ethernet (FCOE), network attached storage (NAS), and NVMe over Fabrics (NVMe-oF).

Hereinafter, the application server 3100₁ and the storage server 3200₁ will mainly be described. A description of the application server 3100₁ may be applied to other application servers 3100₂ to 3100n, and a description of the storage server 3200₁ may be applied to another storage server 3200₂ to 3200m.

The application server 31001 may store data, which is requested by a user or a client to be stored, in (at least) one of the storage servers 3200₁ to 3200m through the network 3300. Also, the application server 3100₁ may obtain data, which is requested by the user or the client to be read, from (at least) one of the storage servers 3200₁ to 3200m through the network 3300. For example, the application server 3100₁ may be implemented as a web server or a database management system (DBMS).

The application server 3100₁ may access a memory 3120n or a storage device 3150n, which is included in another application server 3100n, through the network 3300. In some embodiments, the application server 3100₁ may access memories 3220₁ to 3220m or storage devices 3250₁ to 3250m, which are included in the storage servers 3200₁ to 3200m, through the network 3300. Thus, the application server 3100₁ may perform various operations on data stored in application servers 3100₁ to 3100n and/or the storage servers 3200₁ to 3200m. For example, the application server 3100₁ may execute an instruction for moving or copying data between the application servers 3100₁ to 3100n and/or the storage servers 3200₁ to 3200m. In this case, the data may be moved from the storage devices 3250₁ to 3250m of the storage servers 3200₁ to 3200m to the memories 3120₁ to 3120n of the application servers 3100₁ to 3100n directly or through the memories 3220₁ to 3220m of the storage servers 3200₁ to 3200m. The data moved through the network 3300 may be data encrypted for security or privacy.

The storage server 3200₁ will now be described as an example. An interface 3254₁ may provide physical connection between a processor 3210₁ and a controller 3251₁ and a physical connection between a network inter connect (NIC) 3240₁ and the controller 3251₁. For example, the interface 3254₁ may be implemented using a direct attached storage (DAS) scheme in which the storage device 3250₁ is directly connected with a dedicated cable. For example, the interface 3254₁ may be implemented by using various interface schemes, such as ATA, SATA, e-SATA, an SCSI, SAS, PCI, PCIe, NVMe, IEEE 1394, a USB interface, an SD card interface, an MMC interface, an eMMC interface, a UFS interface, an eUFS interface, and/or a CF card interface.

The storage server 3200₁ may further include a switch 3230₁ and the NIC (Network Inter Connect) 3240₁. The switch 3230₁ may selectively connect the processor 3210₁ to the storage device 3250₁ or selectively connect the NIC 3240₁ to the storage device 3250₁ via the control of the processor 3210₁.

In an example embodiment, the NIC 3240₁ may include a network interface card and a network adaptor. The NIC 3240₁ may be (electrically) connected to the network 3300 by a wired interface, a wireless interface, a Bluetooth interface, or an optical interface. The NIC 3240₁ may include an internal memory, a digital signal processor (DSP), and a host bus interface and be (electrically) connected to the processor 3210₁ and/or the switch 3230₁ through the host bus interface. The host bus interface may be implemented as one of the above-described examples of the interface 3254₁. In an example embodiment, the NIC 3240₁ may be integrated with at least one of the processor 3210₁, the switch 3230₁, and the storage device 3250₁.

In the storage servers 3200₁ to 3200m or the application servers 3100₁ to 3100n, a processor may transmit a command to storage devices 3150₁ to 3150n and 3250₁ to 3250m or the memories 3120₁ to 3120n and 3220₁ to 3220m and program or read data. In this case, the data may be data of which an error is corrected by an ECC engine. The data may be data on which a data bus inversion (DBI) operation or a data masking (DM) operation is performed, and may include cyclic redundancy code (CRC) information. The data may be data encrypted for security or privacy.

The controller 3251₁ may control all operations of the storage device 3250₁. In an example embodiment, the controller 3251₁ may include SRAM. The controller 3251₁ may write data to the NAND flash memory device 3252₁ in response to a write command or read data from the NAND flash memory device 3252₁ in response to a read command. For example, the write command and/or the read command may be provided from the processor 3210₁ of the storage server 3200₁, the processor 3210m of another storage server 3200m, or the processors 3110₁ and 3110n of the application servers 3100₁ and 3100n. DRAM 3253 may temporarily store (or buffer) data to be written to the NAND flash memory device 3252₁ or data read from the NAND flash memory device 3252₁. Also, the DRAM 3253₁ may store metadata. Here, the metadata may be user data or data generated by the controller 3251₁ to manage the NAND flash memory device 3252₁. The storage device 3250₁ may include a secure element (SE) for security or privacy.

All or some of the DRAMs 3253₁ to 3253m may be implemented with the semiconductor memory device according to embodiments of the present disclosure, but the present disclosure is not limited thereto.

As described above, a semiconductor memory device according to embodiments of the present disclosure may include a center-bus circuit which provides paths for data transmission between global write/read circuits or local write/read circuits. The semiconductor memory device may not include additional circuits between the global write/read circuits or the local write/read circuits except for the center-bus circuit and may not include any other additional global or local lines, and the center-bus circuit may be implemented on not the global write/read circuit side but the local write/read circuit side. Accordingly, a semiconductor memory device may implement a byte mode of the semiconductor memory device by using the center-bus circuit and may decrease the complexity or area of the entire data input/output circuit by decreasing the complexity or area of the global write/read circuits.

While the present disclosure has been described with reference to embodiments thereof, it will be apparent to those of ordinary skill in the art that various changes and modifications may be made thereto without departing from the scope of the present disclosure as set forth in the following claims.

What is claimed is:

1. A semiconductor memory device comprising:
a memory cell array including a first storage region and a second storage region;
a plurality of first data pins configured to receive write data in a byte mode of the semiconductor memory device;
a plurality of second data pins configured to be unused in the byte mode and configured to receive the write data in a standard mode of the semiconductor memory device;
a first global write circuit electrically connected to the plurality of first data pins;
a center-bus circuit electrically connected to the first global write circuit and configured to provide the write data to a first connection terminal in a first write mode of writing the write data in the first storage region and to provide the write data to a second connection terminal in a second write mode of writing the write data in the second storage region, wherein the first global write circuit is configured to provide the write data to the center-bus circuit;
a first local write circuit configured to write the write data from the first connection terminal to the first storage region; and
a second local write circuit configured to write the write data from the second connection terminal to the second storage region.

2. The semiconductor memory device of claim 1, wherein the center-bus circuit comprises:
a first center-bus driver configured to receive the write data from the first global write circuit and configured to output the write data to the first local write circuit, in the first write mode; and
a second center-bus driver configured to receive the write data from the first global write circuit and configured to output the write data to the second local write circuit, in the second write mode.

3. The semiconductor memory device of claim 2, wherein the first center-bus driver comprises:
a first multiplexer configured to select and output the write data that is output from the first global write circuit in the first write mode; and
a first center write buffer configured to output the write data that is received from the first multiplexer to the first local write circuit, and
wherein the second center-bus driver comprises:
a second multiplexer configured to select and output the write data that is output from the first global write circuit in the second write mode; and
a second center write buffer configured to output the write data that is received from the second multiplexer to the second local write circuit.

4. The semiconductor memory device of claim 3, further comprising:
a center-bus control circuit configured to generate a center-bus control signal based on a byte mode setting signal and an address signal and to control the center-bus circuit based on the center-bus control signal,
wherein the byte mode setting signal comprises:
a first setting signal and a second setting signal indicating whether the semiconductor memory device is implemented to operate in the byte mode,
wherein the first setting signal is associated with the plurality of first data pins and the second setting signal is associated with the plurality of second data pins, and
wherein the address signal comprises:
an expanded address value indicating that the semiconductor memory device operates in the first write mode or the second write mode.

5. The semiconductor memory device of claim 4, wherein:
the first multiplexer is configured to select the write data that is output from the first global write circuit based on the second setting signal when the first setting signal has a first logic level and the second setting signal has a second logic level; and
the second multiplexer is configured to select the write data that is output from the first global write circuit based on the first setting signal when the first setting signal has the first logic level and the second setting signal has the second logic level.

6. The semiconductor memory device of claim 5, wherein the first center write buffer is configured to output the write data to the first local write circuit based on the expanded address value when the expanded address value has the second logic level.

7. The semiconductor memory device of claim 6, wherein the semiconductor memory device is configured to change a voltage level of a write strobe signal from the second logic level to the first logic level after the first global write circuit outputs the write data to the center-bus circuit, and
wherein the first center write buffer is configured to output the write data to the first local write circuit after the voltage level of the write strobe signal changes from the second logic level to the first logic level.

8. The semiconductor memory device of claim 5, wherein the second center write buffer is configured to output the write data to the second local write circuit based on the expanded address value when the expanded address value has the first logic level.

9. The semiconductor memory device of claim 8, wherein the semiconductor memory device is configured to change the expanded address value from the second logic level to the first logic level after the semiconductor memory device receives an active signal.

10. The semiconductor memory device of claim 3, further comprising:
a second global write circuit electrically connected to the plurality of second data pins,
wherein each of the first center-bus driver and the second center-bus driver is electrically connected to both the first global write circuit and the second global write circuit,
wherein the first center-bus driver is electrically connected to the first local write circuit, and
wherein the second center-bus driver is electrically connected to the second local write circuit.

11. A semiconductor memory device comprising:
a memory cell array including a first storage region and a second storage region, wherein the first storage region has first data, and the second storage region has second data;
a plurality of first data pins configured to output the first data and/or the second data in a byte mode of the semiconductor memory device;
a plurality of second data pins configured to be unused in the byte mode and configured to output the second data in a standard mode of the semiconductor memory device;
a first local read circuit electrically connected to the first storage region and configured to output the first data;
a second local read circuit electrically connected to the second storage region and configured to output the second data;
a center-bus circuit configured to output the first data to a first connection terminal in a first read mode of outputting the first data to the plurality of first data pins and to output the second data to a second connection terminal in a second read mode of outputting the second data to the plurality of first data pins; and
a first global read circuit electrically connected to the plurality of first data pins and configured to output the first data from the first connection terminal to the plurality of first data pins and to output the second data from the second connection terminal to the plurality of first data pins.

12. The semiconductor memory device of claim 11, wherein the center-bus circuit comprises:
a first center-bus driver configured to receive the first data from the first local read circuit to output the first data to the first global read circuit, in the first read mode; and
a second center-bus driver configured to receive the second data from the second local read circuit to output the second data to the first global read circuit, in the second read mode.

13. The semiconductor memory device of claim 12, wherein the first center-bus driver comprises:
a first center read buffer configured to transfer the first data from the first local read circuit to the first global read circuit, in the first read mode; and
a second center read buffer configured to be unused in the first read mode, and
wherein the second center-bus driver comprises:
a third center read buffer configured to transfer the second data from the second local read circuit to the first global read circuit, in the second read mode; and
a fourth center read buffer configured to be unused in the second read mode.

14. The semiconductor memory device of claim 13, further comprising:
a center-bus control circuit configured to generate a center-bus control signal based on a byte mode setting signal and an address signal and to control the center-bus circuit based on the center-bus control signal,
wherein the byte mode setting signal comprises:
a first setting signal and a second setting signal indicating whether the semiconductor memory device is implemented to operate in the byte mode,
wherein the first setting signal is associated with the plurality of first data pins and the second setting signal is associated with the plurality of second data pins, and
wherein the address signal comprises:
an expanded address value indicating that the semiconductor memory device operates in the first read mode or the second read mode.

15. The semiconductor memory device of claim 14, wherein the first center read buffer is configured to output the first data based on the expanded address value when the first setting signal has a first logic level, the second setting signal has a second logic level, and the expanded address value has the second logic level.

16. The semiconductor memory device of claim 14, wherein the third center read buffer is configured to output the second data based on the expanded address value when the first setting signal has a first logic level, the second setting signal has a second logic level, and the expanded address value has the first logic level.

17. The semiconductor memory device of claim 16, wherein the semiconductor memory device is configured to change the expanded address value from the second logic level to the first logic level after the semiconductor memory device receives an active signal.

18. A semiconductor memory device comprising:
a memory cell array including a first storage region and a second storage region;
a plurality of first data pins configured to be used in a byte mode of the semiconductor memory device; and
a center-bus circuit configured to provide a path for data transmission between the plurality of first data pins and the first storage region in a first write/read mode of performing a first write operation or a first read operation on the first storage region and to provide a path for data transmission between the plurality of first data pins and the second storage region in a second write/read mode of performing a second write operation or a second read operation on the second storage region,
wherein the center-bus circuit comprises:
a first multiplexer and a first center write buffer for the first write operation on the first storage region in the first write/read mode; and
a second multiplexer and a second center write buffer for the second write operation on the second storage region in the second write/read mode.

19. The semiconductor memory device of claim 18, wherein the center-bus circuit further comprises:
a first center read buffer and a second center read buffer for the first read operation on the first storage region in the first write/read mode; and
a third center read buffer and a fourth center read buffer for the second read operation on the second storage region in the second write/read mode.

20. The semiconductor memory device of claim 18, wherein the memory cell array comprises:
first sub-memory cell arrays at a first row of the semiconductor memory device; and
second sub-memory cell arrays at a second row of the semiconductor memory device, and
wherein the center-bus circuit is between ones of the first sub-memory cell arrays.
